(19) United States
(12) Patent Application Publication
(10) Pub. No.: US 2026/0206421 A1
(43) Pub. Date: Jul. 16, 2026

(54) DISPLAY DEVICE, ELECTRONIC DEVICE AND METHOD FOR FABRICATING THE SAME

(71) Applicant: Samsung Display Co., Ltd., Yongin-si (KR)

(72) Inventors: Seok Hyun LIM, Yongin-si (KR); Eun Ho SONG, Yongin-si (KR)

(21) Appl. No.: 19/352,838

(22) Filed: Oct. 8, 2025

(30) Foreign Application Priority Data
Jan. 10, 2025 (KR) 10-2025-0003803

(51) Int. Cl. H10K 59/122; H10H 29/37; H10H 29/49; H10K 59/131; H10K 102/00

(52) U.S. Cl. CPC H10K 59/122; H10H 29/37; H10H 29/49; H10K 59/131; H10K 2102/351

(57) ABSTRACT

A display device, a method for fabricating the display device, and an electronic device including the display device are disclosed. The display device may include a substrate including an emission area and a non-emission area; an anode electrode on the emission area; a pixel defining layer provided on the non-emission area of the substrate and covering an edge of the anode electrode; a bank structure including a first bank layer on the pixel defining layer and a second bank layer having a tip protruding toward the emission area further than a side surface of the first bank layer; and a light emitting element layer provided on the anode electrode and including a first light emitting element layer and a second light emitting element layer that are spaced from each other while the bank structure is between the first light emitting element layer and the second light emitting element layer.

### CROSS-REFERENCE TO RELATED APPLICATION

The present application claims priority to and the benefit of Korean Patent Application No. 10-2025-0003803, filed on Jan. 10, 2025, in the Korean Intellectual Property Office, the entire disclosure of which is incorporated herein by reference.

### BACKGROUND

### 1. Field

One or more embodiments of the present disclosure relate to a display device, an electronic device utilizing the display device, and a method for fabricating the display device.

### 2. Description of the Related Art

With the advance of information-oriented society, it is desirable to develop display devices to display images in one or more suitable ways. For example, display devices are employed in one or more suitable electronic devices, such as smartphones, digital cameras, laptop computers, navigation devices, and/or smart televisions. The display device may be a flat panel display device, such as a liquid crystal display device, a field emission display device, and an organic light emitting display device. Among the flat panel display devices, in the light emitting display device, because each of pixels of a display panel includes a light emitting element capable of emitting light by itself, an image may be displayed without a backlight unit providing light to the display panel.

### SUMMARY

One or more aspects of embodiments of the present disclosure are directed toward a display device (e.g., a high-resolution display device) in which a leakage current defect caused by a light emitting element layer is solved (or a degree or occurrence of a leakage current defect caused by a light emitting element layer is reduced), an electronic device utilizing the display device, and a method for fabricating the display device.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

Other aspects and features of embodiments of the present disclosure may be apparent from the following detailed description and the accompanying drawings.

According to one or more embodiments of the present disclosure, a display device includes: a substrate including an emission area and a non-emission area; an anode electrode located or provided on the emission area of the substrate; a pixel defining layer located or provided on the non-emission area of the substrate and covering an edge of the anode electrode; a bank structure including a first bank layer located or provided on the pixel defining layer and a second bank layer having a tip protruding toward the emission area further than a side surface of the first bank layer; and a light emitting element layer located or provided on the anode electrode and including a first light emitting element layer and a second light emitting element layer that are spaced and/or apart (e.g., spaced apart or separated) from each other while the bank structure is between the first light emitting element layer and the second light emitting element layer, wherein the tip of the second bank layer has a reverse tapered shape, and a thickness of the tip of the second bank layer is greater than or equal to a thickness of the first bank layer.

In one or more embodiments, the first bank layer and the second bank layer may contain an inorganic insulating (e.g., electrically insulating) material.

In one or more embodiments, the first bank layer and the second bank layer may contain different materials.

In one or more embodiments, the tip of the second bank layer may include a first surface being adjacent to (e.g., facing) the first bank layer, a second surface being opposite to (e.g., facing) the first surface, and a side surface connecting the first surface and the second surface to each other, and a width of the first surface of the tip may be less than a width of the second surface of the tip.

In one or more embodiments, the width of the second surface of the tip may have a value greater than the thickness of the first bank layer.

In one or more embodiments, a first inclination angle formed by (e.g., between) the first surface and the side surface may be an obtuse angle, and a second inclination angle formed by (e.g., between) the second surface and the side surface may be an acute angle.

In one or more embodiments, the second inclination angle may be less than or equal to 50 degrees.

In one or more embodiments, the pixel defining layer may define an opening, the tip of the second bank layer may be located or provided to be around (e.g., to surround) the opening, and a side surface of the pixel defining layer may protrude toward the emission area further than the side surface of the first bank layer.

In one or more embodiments, the display device may further include a cathode electrode located or provided on the light emitting element layer; and an organic pattern located or provided on the second bank layer, containing substantially the same material as the light emitting element layer, and being spaced and/or apart (e.g., spaced apart or separated) from the light emitting element layer, wherein the cathode electrode may completely (e.g., substantially completely) cover the organic pattern.

In one or more embodiments, the light emitting element layer may include at least one of a hole injection layer, a hole transport layer, and an electron transport layer.

In one or more embodiments, the anode electrode may include a first anode electrode and a second anode electrode that are spaced and/or apart (e.g., spaced apart or separated) from each other while the pixel defining layer is between the first anode electrode and the second anode electrode, and the first anode electrode and the second anode electrode may be located or provided at different heights.

In one or more embodiments, the display device may further include a first metal pattern located or provided between the substrate and the first anode electrode; and a second metal pattern located or provided between the substrate and the second anode electrode, wherein the first metal pattern includes a first insulating (e.g., electrically insulating) layer, and the second metal pattern includes a second insulating (e.g., electrically insulating) layer, and a thickness of the first insulating layer and a thickness of the second insulating layer may be different from each other.

According to one or more embodiments of the present disclosure, a method for fabricating a display device includes: forming or providing a temporary protective layer having a normal tapered shape on an anode electrode; forming or providing a pixel defining layer, a first bank layer, and a second bank layer that cover the temporary protective layer; forming or providing a tip of the second bank layer and an opening of the pixel defining layer by performing an etching process; and forming or providing a light emitting layer and a cathode electrode on the anode electrode, wherein in the forming or providing of the pixel defining layer, the first bank layer, and the second bank layer that cover the temporary protective layer, a thickness of the second bank layer is greater than or equal to a thickness of the first bank layer.

In one or more embodiments, in the forming or providing of the pixel defining layer, the first bank layer, and the second bank layer that cover the temporary protective layer, the pixel defining layer, the first bank layer, and the second bank layer may cover the temporary protective layer along its shape to have a stepped portion in a normal tapered shape.

In one or more embodiments, in the forming or providing of the tip of the second bank layer and the opening of the pixel defining layer by performing the etching process, the tip of the second bank layer may have a reverse tapered shape.

According to one or more embodiments of the present disclosure, an electronic device includes: at least one display device including a substrate including an emission area and a non-emission area; and at least one selected from among a processor, a memory, and a power module that are connected to the at least one display device, wherein the at least one display device further includes: an anode electrode located or provided on the emission area of the substrate; a pixel defining layer located or provided on the non-emission area of the substrate and covering an edge of the anode electrode; a bank structure including a first bank layer located or provided on the pixel defining layer and a second bank layer having a tip protruding toward the emission area further than a side surface of the first bank layer; and a light emitting element layer located or provided on the anode electrode and including a first light emitting element layer and a second light emitting element layer that are spaced and/or apart (e.g., spaced apart or separated) from each other while the bank structure is between the first light emitting element layer and the second light emitting element layer, wherein the tip of the second bank layer has a reverse tapered shape, and a thickness of the tip of the second bank layer is greater than or equal to a thickness of the first bank layer.

According to the display device as described in one or more embodiments, the electronic device utilizing the display device, and the method for fabricating the display device, it may be feasible to provide a high-resolution display device in which a leakage current defect caused by the light emitting element layer is solved (or in which a degree or occurrence of a leakage current defect caused by the light emitting element layer is reduced) and an electronic device utilizing the high-resolution display device.

It should be noted that the aspects, effects, and/or embodiments of the present disclosure are not limited to those described herein, and the above and other aspects, effects, and/or embodiments of the present disclosure will be more apparent to those skilled in the art from the following descriptions.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is an exploded perspective view illustrating a display device according to one or more embodiments;

FIG. 2 is a block diagram illustrating a display device according to one or more embodiments;

FIG. 3 is an equivalent circuit diagram of a pixel according to one or more embodiments;

FIG. 4 is a plan view illustrating the arrangement of a plurality of pixels located or provided in the display area of FIG. 2;

FIG. 5 is a cross-sectional view of a display device according to one or more embodiments taken along the line X1-X1′ of FIG. 4;

FIG. 6 is an enlarged cross-sectional view of the light emitting element in FIG. 5;

FIG. 7 is an enlarged cross-sectional view of the display element layer overlapping the first emission area in FIG. 5;

FIG. 8 is an enlarged cross-sectional view of the area “A” of FIG. 7;

FIG. 9 is an enlarged cross-sectional view of a display element layer overlapping a non-emission area located or provided between the first emission area and the second emission area in FIG. 5;

FIG. 10 is a cross-sectional view of a display device according to one or more embodiments, taken along the line X1-X1′ of FIG. 4;

FIG. 11 is a flowchart illustrating a method for fabricating the display element layer in FIG. 5;

FIG. 12 is a cross-sectional view illustrating the method (e.g., step) S100 of FIG. 11;

FIGS. 13 and 14 are cross-sectional views illustrating the method (e.g., step) S200 of FIG. 11;

FIGS. 15-19 are cross-sectional views illustrating the method (e.g., step) S300 of FIG. 11;

FIG. 20 is a cross-sectional view illustrating the method (e.g., step) S400 of FIG. 11;

FIG. 21 is a block diagram of an electronic device according to one or more embodiments; and

FIG. 22 is schematic views of electronic devices according to one or more embodiments.

### DETAILED DESCRIPTION

The subject matter of the present disclosure will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete and will fully convey the aspects and features of the present disclosure to those skilled in the art.

The singular forms “a,” “an,” and “the” include plural references unless the context clearly requires otherwise.

As used herein, the term “and/or” includes any and all combinations of one or more of the associated listed items. For example, “A and/or B” indicates cases where it is A, B, or both (e.g., simultaneously) A and B.

The utilization of “may” if (e.g., when) describing embodiments of the present disclosure refers to “one or more embodiments of the present disclosure.”

In the context of the present disclosure and unless otherwise defined, the terms “use,” “using,” and “used” may be considered synonymous with the terms, “utilize,” “utilizing,” and “utilized” respectively.

Throughout the disclosure, the expression “at least one of a, b, and c” indicates only a, only b, only c, both (e.g., simultaneously) a and b, both (e.g., simultaneously) a and c, both (e.g., simultaneously) b and c, all of a, b, and c, or variations thereof.

It is also to be understood that if (e.g., when) a layer is referred to as being “on” another layer or substrate, it may be directly on the other layer or substrate, or one or more intervening layers may also be present therebetween. In contrast, if (e.g., when) a layer is referred to as being “directly on” another layer or substrate, there are no intervening layers present therebetween.

The same reference numerals indicate substantially the same components throughout the specification.

It is to be understood that, although the terms “first,” “second,” and/or the like may be used herein to describe one or more elements, these elements should not be limited by these terms. These terms are used to distinguish one element from another element. For instance, a first element as described herein may be termed a second element without departing from the scope of the present disclosure. Similarly, the second element may also be termed a first element.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “substantially,” “about,” and/or the like are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction (e.g., DR3) refers to a top-down view of the object, as if (e.g., when) looking directly down onto the surface from above. In this context, the z-axis direction is perpendicular or normal to the horizontal plane defined by x-axis and y-axis directions (e.g., DR1 and DR2).

Unless otherwise defined, all terms (including technical and scientific terms) used herein have substantially the same meaning as generally understood by one of ordinary skill in the art to which the present disclosure pertains. It is also to be understood that terms defined in dictionaries that are generally available or generally used should be interpreted as having meanings consistent with the meanings in the context of the related art and are expressly defined herein unless they are interpreted in an ideal or overly formal sense.

Hereinafter, one or more embodiments of the present disclosure will be described in more detail with reference to the accompanying drawings.

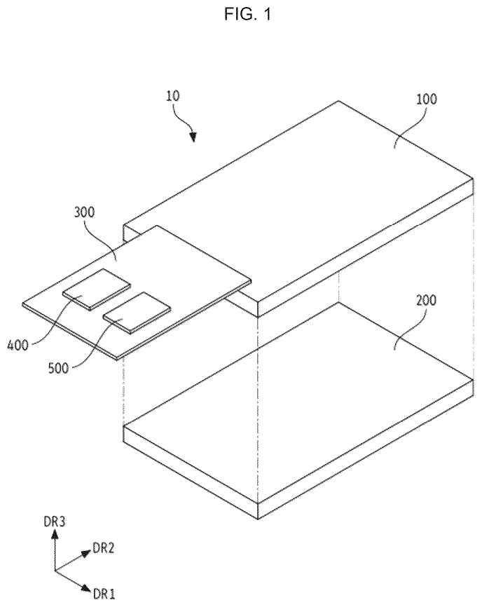

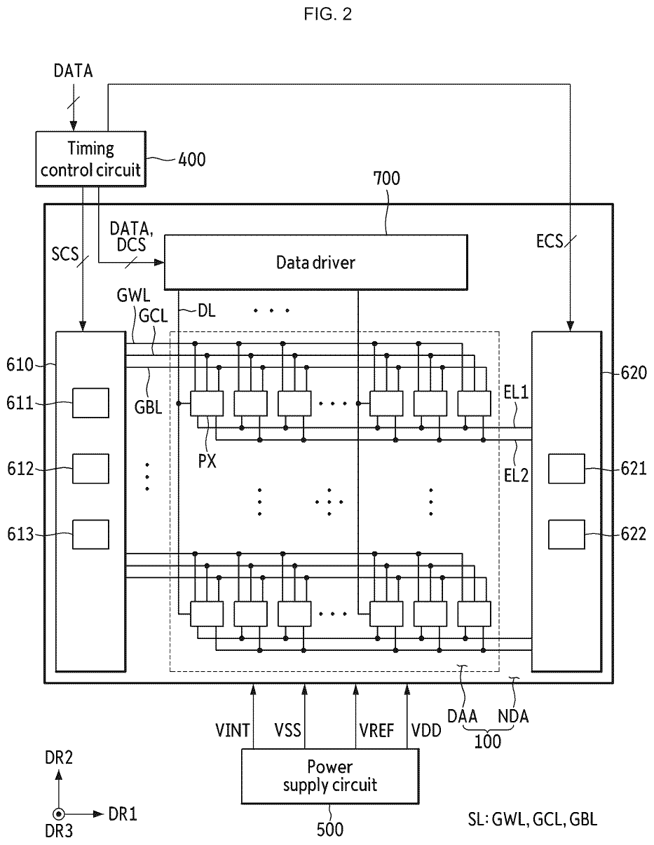

FIG. 1 is an exploded perspective view illustrating a display device according to one or more embodiments. FIG. 2 is a block diagram illustrating a display device according to one or more embodiments.

Referring to FIGS. 1 and 2, a display device 10 according to one or more embodiments may be a device to display a moving image and/or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. In one or more embodiments, the display device 10 according to one or more embodiments may be applied to a smart watch, a watch phone, a head mounted display (HMD) to implement virtual reality and/or augmented reality, and/or the like.

The display device 10 according to one or more embodiments may include a display panel 100, a heat dissipation layer 200, a circuit board 300, a timing control circuit 400, and a power supply circuit 500.

The display panel 100 may have a planar shape (e.g., a substantially planar shape) similar to a quadrilateral shape (e.g., a substantially quadrilateral shape). For example, the display panel 100 may have a planar shape (e.g., a substantially planar shape) similar to a quadrilateral shape (e.g., a substantially quadrilateral shape), having a short side in a first direction DR1 and a long side in a second direction DR2 crossing (e.g., intersecting) the first direction DR1. However, an embodiment of the present application is not limited thereto, for example, as shown in FIG. 2, the display panel 100 may have a planar shape similar to a quadrilateral shape having a long side in a first direction DR1 and a short side in a second direction DR2. In the display panel 100, a corner where a short side in the first direction DR1 and a long side in the second direction DR2 meet may be right-angled or rounded with a selected (e.g., set or predetermined) curvature. The planar shape of the display panel 100 is not limited to a quadrilateral shape (e.g., a substantially quadrilateral shape) and may be a shape similar to another polygonal shape (e.g., substantially polygonal shape), a circular shape (e.g., a substantially circular shape), or an elliptical shape (e.g., a substantially elliptical shape). The planar shape of the display device 10 may conform to the planar shape of the display panel 100, but embodiments of the present disclosure are not limited thereto.

The display panel 100 may include a display area DAA that displays an image and a non-display area NDA that does not display an image as illustrated in FIG. 2.

A plurality of pixels PX, a plurality of scan lines SL, a plurality of emission control lines EL1 and EL2, and a plurality of data lines DL may be located or provided in a portion overlapping the display area DAA.

The plurality of scan lines SL and the plurality of emission control lines EL1 and EL2 may extend in the first direction DR1 and be located or provided in the second direction DR2. Further, the plurality of data lines DL may extend in the second direction DR2, while being located or provided in the first direction DR1. In one or more embodiments, the plurality of scan lines SL may include a plurality of write scan lines GWL, a plurality of control scan lines GCL, and a plurality of bias scan lines GBL. The plurality of emission control lines EL1 and EL2 may include a plurality of first emission control lines EL1 and a plurality of second emission control lines EL2.

The plurality of pixels PX may be arranged or provided in a matrix form in the first direction DR1 and the second direction DR2. Each of the pixels PX may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and/or any one of the plurality of data lines DL. Each of the pixels PX may receive the data voltage of the data line DL according to the write scan signal of the write scan line GWL and may emit light from a light emitting element according to the data voltage.

The scan driver 610, the emission driver 620, and the data driver 700 may be located or provided in a portion overlapping the non-display area NDA.

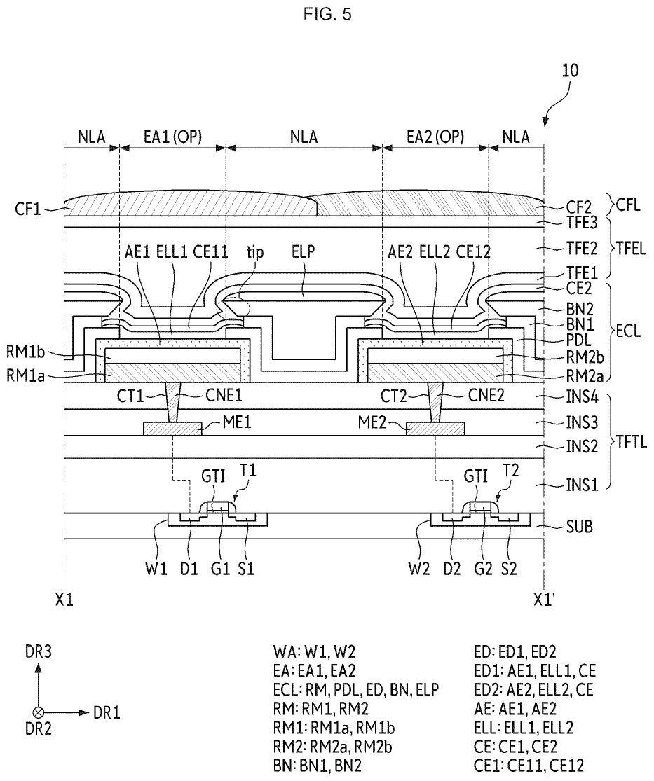

The scan driver 610 may include a plurality of scan transistors, and the emission driver 620 may include a plurality of light emitting transistors. The plurality of scan transistors and the plurality of light emitting transistors may be formed or provided on a semiconductor substrate (or a substrate) SUB (see FIG. 5) through a semiconductor process. For example, the plurality of scan transistors and the plurality of light emitting transistors may be formed or provided as complementary metal-oxide-semiconductor (CMOS) transistors. Although it is illustrated in FIG. 2 that the scan driver 610 is located or provided on the left side of the display area DAA and the emission driver 620 is located or provided on the right side of the display area DAA, embodiments of the present disclosure are not limited thereto. For example, the scan driver 610 and the emission driver 620 may be located or provided on both (e.g., simultaneously) the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed or provided on the semiconductor substrate SUB (see FIG. 5) through a semiconductor process. For example, the plurality of data transistors may be formed or provided as CMOS transistors.

The data driver 700 may receive digital video data DATA and a data timing control signal DCS from the timing control circuit 400. The data driver 700 may convert the digital video data DATA into analog data voltages according to the data timing control signal DCS and output the analog data voltages to data lines DL. In this case, at least one of the plurality of pixels PX may be selected by the write scan signal of the scan driver 610, and the data voltages may be supplied to the selected pixel PX.

The heat dissipation layer 200 may overlap the display panel 100 in a third direction DR3, which is a thickness direction of the display panel 100. The heat dissipation layer 200 may be located or provided on one surface, e.g., the rear surface, of the display panel 100. The heat dissipation layer 200 may serve to dissipate heat generated from the display panel 100. The heat dissipation layer 200 may include a metal layer and/or non-metal layer having high thermal conductivity, such as graphite, silver (Ag), copper (Cu), and/or aluminum (Al).

The circuit board 300 may be electrically connected to a plurality of pads of the display panel 100 by utilizing a conductive (e.g., electrically conductive) adhesive member, such as an anisotropic conductive film. The circuit board 300 may be a flexible printed circuit board having a flexible material and/or a flexible film. Although the circuit board 300 is illustrated in FIG. 1 as being unfolded, the circuit board 300 may be bent. In this case, one end of the circuit board 300 may be located or provided on the rear surface of the display panel 100 and/or the rear surface of the heat dissipation layer 200. One end of the circuit board 300 may be opposite to the other end of the circuit board 300 connected to a pad portion of the display panel 100 by utilizing a conductive (e.g., electrically conductive) adhesive member.

The timing control circuit 400 may receive digital video data DATA and timing signals inputted from the outside. The timing control circuit 400 may generate the scan timing control signal SCS, the emission timing control signal ECS, and the data timing control signal DCS to control the display panel 100 in response to the timing signals. The timing control circuit 400 may output the scan timing control signal SCS to the scan driver 610 and output the emission timing control signal ECS to the emission driver 620. The timing control circuit 400 may output the digital video data DATA and the data timing control signal DCS to the data driver 700.

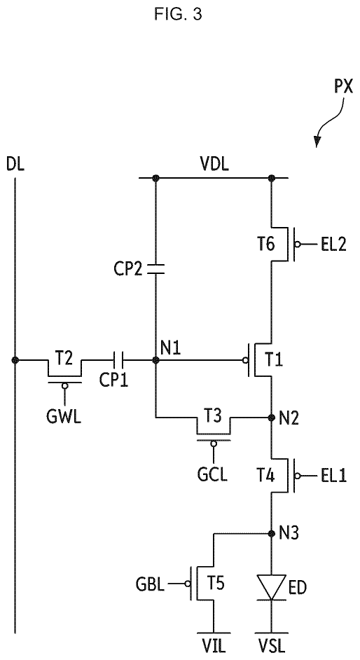

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described herein in more detail in conjunction with FIG. 3. In addition, the power supply circuit 500 may also generate a reference voltage VREF.

Each of the timing control circuit 400 and the power supply circuit 500 may be formed or provided as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be located or provided in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed or provided on the semiconductor substrate SUB (see FIG. 5) through a semiconductor process. For example, the plurality of timing transistors and the plurality of power transistors may be formed or provided as CMOS transistors.

FIG. 3 is an equivalent circuit diagram of a pixel according to one or more embodiments.

Referring to FIG. 3, the pixel PX may be connected to the write scan line GWL, the control scan line GCL, the bias scan line GBL, the first emission control line EL1, the second emission control line EL2, and the data line DL. In one or more embodiments, the pixel PX may be connected to the first driving voltage line VSL to which the first driving voltage VSS corresponding to a low potential voltage is applied, the second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The pixel PX may include a plurality of transistors T1 to T6, a light emitting element ED, a first capacitor CP1, and a second capacitor CP2.

The light emitting element ED may emit light according to a driving current that flows through the channel of the first transistor T1. A light emission amount of the light emitting element ED may be proportional to the driving current. The light emitting element ED may be located or provided between the fourth transistor T4 and the first driving voltage line VSL. The first electrode of the light emitting element ED may be connected to the drain electrode of the fourth transistor T4, and the second electrode of the light emitting element ED may be connected to the first driving voltage line VSL. The first electrode of the light emitting element ED may be an anode electrode, and the second electrode of the light emitting element ED may be a cathode electrode. The light emitting element ED may be an organic light emitting diode including a first electrode, a second electrode, and an organic light emitting layer located or provided between the first electrode and the second electrode, but embodiments of the present disclosure are not limited thereto. For example, the light emitting element ED may be an inorganic light emitting element including a first electrode, a second electrode, and an inorganic semiconductor located or provided between the first electrode and the second electrode, in which case the light emitting element ED may be a micro light emitting diode.

The first transistor T1 may be a driving transistor that controls a source-drain current (hereinafter referred to as “driving current”) that flows between the source electrode and the drain electrode according to a voltage applied to the gate electrode. The first transistor T1 may include a gate electrode connected to a first node N1, a source electrode connected to the drain electrode of a sixth transistor T6, and a drain electrode connected to a second node N2.

A second transistor T2 may be located or provided between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be located or provided between a first node N1 and a second node N2. The third transistor T3 may be turned on by the control scan signal of the control scan line GCL to connect the first node N1 to the second node N2. For this reason, because the gate electrode and the drain electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element ED. The fourth transistor T4 may include a gate electrode connected to the first emission control line EL1, a source electrode connected to the second node N2, and a drain electrode connected to the third node N3.

A fifth transistor T5 may be located or provided between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element ED. The fifth transistor T5 may include a gate electrode connected to the bias scan line GBL, a source electrode connected to the third node N3, and a drain electrode connected to the third driving voltage line VIL.

The sixth transistor T6 may be located or provided between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed or provided between the first node N1 and the drain electrode of the second transistor T2. The first capacitor CP1 may include one electrode connected to the drain electrode of the second transistor T2 and the other electrode connected to the first node N1.

The second capacitor CP2 may be formed or provided between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element ED.

Each of the first to sixth transistors T1 to T6 may be a metal-oxide-semiconductor field effect transistor (MOSFET). For example, each of the first to sixth transistors T1 to T6 may be a positive type or kind (P-type or kind) MOSFET, but embodiments of the present disclosure are not limited thereto. Each of the first to sixth transistors T1 to T6 may be a negative type or kind (N-type or kind) MOSFET. In one or more embodiments, one or more of the first to sixth transistors T1 to T6 may be P-type or kind MOSFETs, and each of the remaining transistors may be an N-type or kind MOSFET.

Although it is illustrated in FIG. 3 that the pixel PX includes the six transistors T1 to T6 and the two capacitors CP1 and CP2, it should be noted that the equivalent circuit diagram of the pixel PX is not limited to the example as illustrated in FIG. 3. For example, the number of the transistors and the number of the capacitors of the pixel PX are not limited to the example as illustrated in FIG. 3.

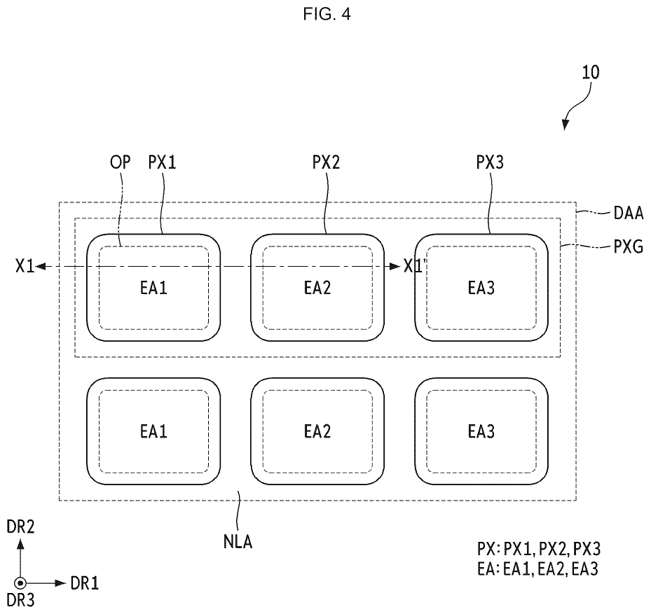

FIG. 4 is a plan view illustrating the arrangement of a plurality of pixels located or provided in the display area of FIG. 2.

Referring to FIG. 4, in one or more embodiments, the plurality of pixels PX may be located or provided in a portion overlapping the display area DAA. For example, the pixel PX may include a first pixel PX1, a second pixel PX2, and a third pixel PX3, and the first pixel PX1, the second pixel PX2, and the third pixel PX3 may be spaced and/or apart (e.g., spaced apart or separated) from each other.

In one or more embodiments, the first pixel PX1, the second pixel PX2, and the third pixel PX3 may constitute a pixel group PXG. The pixel group PXG may be a minimum unit that emits white light. However, the type or kind and/or number of pixels PX constituting the pixel group PXG may be suitably changed according to one or more embodiments.

The first pixel PX1, the second pixel PX2, and the third pixel PX3 may include different emission areas EA. For example, a first emission area EA1 included in the first pixel PX1 may emit red light of a first color, a second emission area EA2 included in the second pixel PX2 may emit green light of a second color, and a third emission area EA3 included in the third pixel PX3 may emit blue light of a third color, but embodiments of the present disclosure are not limited thereto. In one or more embodiments, the first emission area EA1 included in the first pixel PX1 may emit blue light of the third color, the second emission area EA2 included in the second pixel PX2 may emit green light of the second color, and the third emission area EA3 included in the third pixel PX3 may emit red light of the first color.

In the drawing, the size and shape of each of the first to third emission areas EA1, EA2, and EA3 are illustrated to be substantially the same, but are not limited thereto. The size and shape of each of the first to third emission areas EA1, EA2, and EA3 may be freely or suitably adjusted according to the required or desired characteristics.

A non-emission area NLA in one or more embodiments may be located or provided to be around (e.g., to surround) each of the first to third emission areas EA1, EA2, and EA3. The non-emission area NLA may assist in preventing the lights emitted from the respective first to third emission areas EA1, EA2, and EA3 from being mixed (or reducing a degree to or occurrence of which the lights emitted from the respective first to third emission areas EA1, EA2, and EA3 are mixed).

FIG. 5 is a cross-sectional view of a display device according to one or more embodiments taken along the line X1-X1′ of FIG. 4. FIG. 5 is a schematic cross-sectional view of the display device 10 overlapping the first emission area EA1 included in the first pixel PX1 and the second emission area EA2 included in the second pixel PX2. As described in one or more embodiments, the first emission area EA1 may emit at least one of red light and blue light, and the second emission area EA2 may emit green light.

Referring to FIG. 5, the display device 10 may include a substrate SUB, a transistor layer TFTL, a display element layer ECL, and an encapsulation layer TFEL.

The substrate SUB may be a silicon substrate, a germanium substrate, or a silicon-germanium substrate.

The substrate SUB may be replaced with a glass substrate and/or a polymer resin substrate, such as polyimide. In this case, thin film transistors may be located or provided on the glass substrate and/or the polymer resin substrate. The glass substrate may be a rigid substrate that does not bend, and the polymer resin substrate may be a flexible substrate that may be bent or curved.

In one or more embodiments, a plurality of wells WA may be located or provided in the substrate SUB.

The substrate SUB may be a substrate doped with a first type or kind impurity, and the plurality of wells WA may be regions doped with a second type or kind impurity. For example, the second type or kind impurity may be different from the first type or kind impurity. For example, if (e.g., when) the first type or kind impurity is a P-type or kind impurity, the second type or kind impurity may be an N-type or kind impurity. In one or more embodiments, if (e.g., when) the first type or kind impurity is an N-type or kind impurity, the second type or kind impurity may be a P-type or kind impurity.

The transistor layer TFTL may be located or provided on the substrate SUB. The transistor layer TFTL may include the first and second transistors T1 and T2 and a plurality of insulating (e.g., electrically insulating) layers.

The first transistor T1 may be a transistor provided in the first pixel PX1. For example, the first transistor T1 may be any one of the transistors as illustrated in FIG. 3. The first transistor T1 may include a first gate G1, a first source S1, and a first drain D1. The first source S1 and the first drain D1 may be located or provided in the first well W1. A gate insulating layer GTI may be located or provided between the first gate G1 and the first well W1. A channel of the first transistor T1 may be formed or provided in the first well W1 between the first source S1 and the first drain D1.

The second transistor T2 may be a transistor provided in the second pixel PX2. The second transistor T2 may include a second gate G2, a second source S2, and a second drain D2. The second source S2 and the second drain D2 may be located or provided in a second well W2. The gate insulating layer GTI may be located or provided between the second gate G2 and the second well W2. A channel of the second transistor T2 may be formed or provided in the second well W2 between the second source S2 and the second drain D2.

A first insulating layer INS1 may be located or provided on the first transistor T1 and the second transistor T2. The first insulating layer INS1 may include an inorganic insulating (e.g., electrically insulating) material and may include, for example, silicon oxide (e.g., SiOₓ, wherein 0<x≤2; e.g., SiO₂).

A second insulating layer INS2 may be located or provided on the first insulating layer INS1. The second insulating layer INS2 may include an inorganic insulating (e.g., electrically insulating) material and may include, for example, at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

A first intermediate electrode ME1 and a second intermediate electrode ME2 may be located or provided on the second insulating layer INS2. The first intermediate electrode ME1 may be connected to the first drain D1 of the first transistor T1 through a contact hole penetrating the first insulating layer INS1 and the second insulating layer INS2, and the second intermediate electrode ME2 may be connected to the second drain D2 of the second transistor T2 through another contact hole penetrating the first insulating layer INS1 and the second insulating layer INS2.

The third insulating layer INS3 may be located or provided on the first intermediate electrode ME1 and the second intermediate electrode ME2. The third insulating layer INS3 may entirely (e.g., substantially entirely) cover the first intermediate electrode ME1 and the second intermediate electrode ME2. The third insulating layer INS3 may include an inorganic insulating (e.g., electrically insulating) material and may include, for example, at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

A fourth insulating layer INS4 may be located or provided on the third insulating layer INS3. The fourth insulating layer INS4 may include an inorganic insulating (e.g., electrically insulating) material and may include, for example, at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

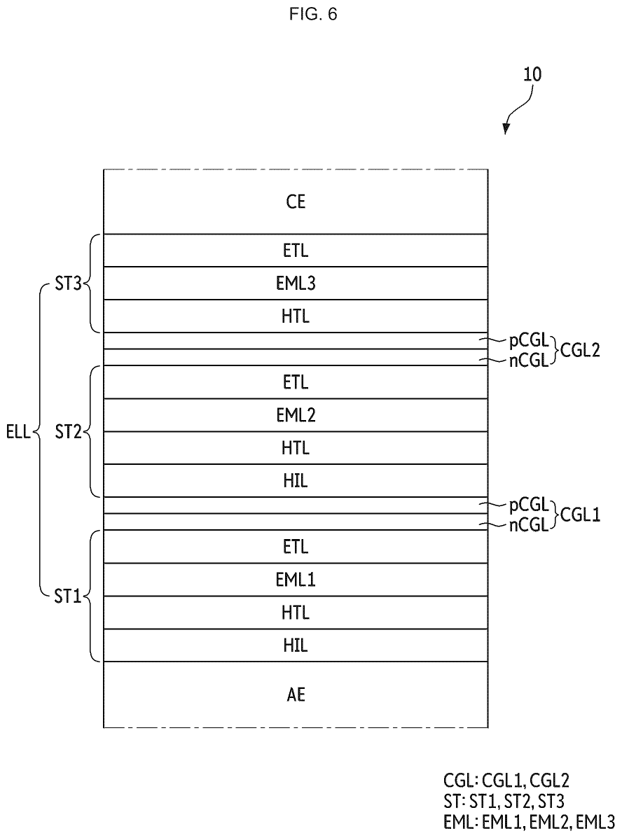

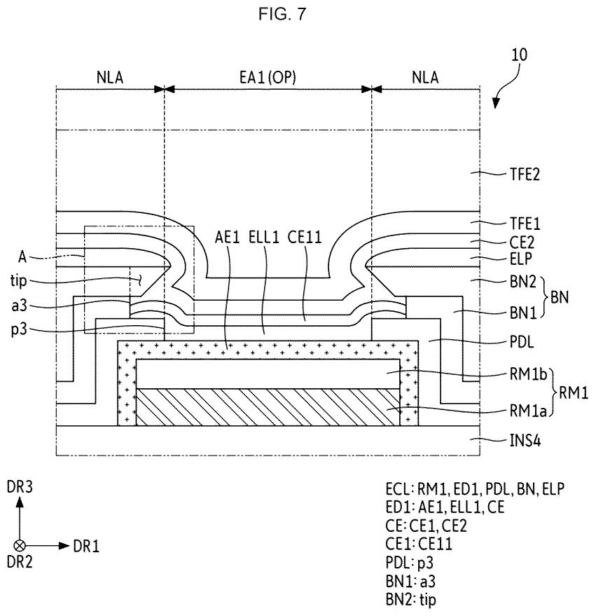

FIG. 6 is an enlarged cross-sectional view of the light emitting element in FIG. 5, and FIG. 7 is an enlarged cross-sectional view of the display element layer overlapping the first emission area in FIG. 5.

Referring to FIGS. 5 to 7, the display element layer ECL may be located or provided on the transistor layer TFTL. The display element layer ECL may include a metal pattern RM, a pixel defining layer PDL, the light emitting element ED, a bank structure BN, and organic pattern ELP.

The metal pattern RM may be located or provided on the fourth insulating layer INS4 in a portion overlapping the emission area EA. The metal pattern RM may reflect light emitted from the light emitting element ED or light incident from the outside.

The metal pattern RM may include a first metal pattern RM1 and a second metal pattern RM2. The first metal pattern RM1 and the second metal pattern RM2 may be spaced and/or apart (e.g., spaced apart or separated) from each other. For example, the first metal pattern RM1 may be located or provided in a portion overlapping the first emission area EA1 of the first pixel PX1, and the second metal pattern RM2 may be located or provided in a portion overlapping the second emission area EA2 of the second pixel PX2.

The first metal pattern RM1 may be connected to the first intermediate electrode ME1 through a first contact hole CT1 penetrating the third insulating layer INS3 and the fourth insulating layer INS4. For example, the first metal pattern RM1 may be connected to the first intermediate electrode ME1 through a first connection electrode CNE1 in the first contact hole CT1.

The second metal pattern RM2 may be connected to the second intermediate electrode ME2 through a second contact hole CT2 penetrating the third insulating layer INS3 and the fourth insulating layer INS4. For example, the second metal pattern RM2 may be connected to the second intermediate electrode ME2 through a second connection electrode CNE2 in the second contact hole CT2. The first connection electrode CNE1 and the second connection electrode CNE2 may include a material containing tungsten (W).

In one or more embodiments, the first metal pattern RM1 may include a first reflective electrode RM1a and a first insulating layer RM1b.

The first reflective electrode RM1a of the first metal pattern RM1 may be located or provided on the fourth insulating layer INS4. The first reflective electrode RM1a may be located or provided in contact with the fourth insulating layer INS4.

The first reflective electrode RM1a may be a metal layer containing metal, such as silver (Ag), magnesium (Mg), aluminum (Al), platinum (Pt), palladium (Pd), gold (Au), nickel (Ni), neodymium (Nd), iridium (Ir), or chromium (Cr), and/or a metal compound layer containing a compound thereof. In one or more embodiments, the first reflective electrode RM1a may contain titanium (Ti) and/or titanium nitride (e.g., TiNₓ, wherein 0<x≤2; e.g., TiN) located or provided in the upper end and/or the lower end of the metal layer. In one or more embodiments, the first reflective electrode RM1a may further include a metal oxide layer (e.g., a transparent (e.g., substantially transparent) conductive (e.g., electrically conductive) oxide layer) located or provided in the upper end and/or the lower end of the metal layer.

The first insulating layer RM1b may be located or provided on the first reflective electrode RM1a. The first insulating layer RM1b may be a resonance auxiliary layer of the first light emitting element ED1. For example, the first insulating layer RM1b may have a height or thickness that may cause constructive interference if (e.g., when) light emitted from the first light emitting element ED1 is reflected by the first metal pattern RM1. Accordingly, the first metal pattern RM1 may increase or enhance the luminous efficiency of the first light emitting element ED1.

The first insulating layer RM1b may include an inorganic insulating (e.g., electrically insulating) material. For example, the first insulating layer RM1b may include at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

In one or more embodiments, the second metal pattern RM2 may include a second reflective electrode RM2a and a second insulating layer RM2b.

The second reflective electrode RM2a of the second metal pattern RM2 may be located or provided on the fourth insulating layer INS4. The second reflective electrode RM2a may be located or provided in contact with the fourth insulating layer INS4.

The second reflective electrode RM2a may be a metal layer containing metal, such as silver (Ag), magnesium (Mg), aluminum (Al), platinum (Pt), palladium (Pd), gold (Au), nickel (Ni), neodymium (Nd), iridium (Ir), or chromium (Cr), and/or a metal compound layer containing a compound thereof. In one or more embodiments, the second reflective electrode RM2a may contain titanium (Ti) and/or titanium nitride (e.g., TiNₓ, wherein 0<x≤2; e.g., TiN) located or provided in the upper end and/or the lower end of the metal layer. In one or more embodiments, the second reflective electrode RM2a may further include a metal oxide layer (e.g., a transparent (e.g., substantially transparent) conductive (e.g., electrically conductive) oxide layer) located or provided in the upper end and/or the lower end of the metal layer.

In one or more embodiments, the first reflective electrode RM1a and the second reflective electrode RM2a may have substantially the same thickness.

The second insulating layer RM2b may be located or provided on the second reflective electrode RM2a. The second insulating layer RM2b may be a resonance auxiliary layer of the second light emitting element ED2. For example, the second insulating layer RM2b may have a thickness that may cause constructive interference if (e.g., when) light emitted from the second light emitting element ED2 is reflected by the second reflective electrode RM2a. Accordingly, the second metal pattern RM2 may increase or enhance the luminous efficiency of the second light emitting element ED2.

The second insulating layer RM2b may include an inorganic insulating (e.g., electrically insulating) material. For example, the second insulating layer RM2b may include at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

In one or more embodiments, the first insulating layer RM1b and the second insulating layer RM2b may have different thicknesses.

The light emitting element ED may be located or provided on the metal pattern RM. The light emitting element ED may include the first light emitting element ED1 located or provided on the first metal pattern RM1 in a portion overlapping the first emission area EA1, and the second light emitting element ED2 located or provided on the second metal pattern RM2 in a portion overlapping the second emission area EA2.

The first light emitting element ED1 may include a first anode electrode AE1, a first light emitting element layer ELL1, and a cathode electrode CE, and the second light emitting element ED2 may include a second anode electrode AE2, a second light emitting element layer ELL2, and a cathode electrode CE.

In one or more embodiments, the anode electrode AE may be located or provided on the metal pattern RM.

The anode electrode AE may include any one of copper (Cu), aluminum (Al), tungsten (W), molybdenum (Mo), chromium (Cr), gold (Au), titanium (Ti), nickel (Ni), and neodymium (Nd), an alloy containing any one selected from among them, or a transparent (e.g., substantially transparent) conductive (e.g., electrically conductive) oxide. For example, the anode electrode AE may contain titanium nitride (e.g., TiNₓ, wherein 0<x≤2; e.g., TiN), indium tin oxide (ITO), and/or indium zinc oxide (IZO), but embodiments of the present disclosure are not limited thereto.

The anode electrode AE may include the first anode electrode AE1 located or provided in a portion overlapping the first emission area EA1 and the second anode electrode AE2 located or provided in a portion overlapping the second emission area EA2. The first anode electrode AE1 and the second anode electrode AE2 may be spaced and/or apart (e.g., spaced apart or separated) from each other while the pixel defining layer PDL is between the first anode electrode AE1 and the second anode electrode AE2.

The first anode electrode AE1 may be located or provided in contact with and on the first metal pattern RM1 and may be connected to the first connection electrode CNE1, the first intermediate electrode ME1, and the first transistor T1 through the first metal pattern RM1. Although the drawing illustrates that the first anode electrode AE1 entirely (e.g., substantially entirely) covers the first metal pattern RM1, embodiments of the present disclosure are not limited thereto. The first anode electrode AE1 may be formed or provided to cover the top surface of the first metal pattern RM1.

The second anode electrode AE2 may be located or provided in contact with and on the second metal pattern RM2 and may be connected to the second connection electrode CNE2, the second intermediate electrode ME2, and the second transistor T2 through the second metal pattern RM2. Redundant descriptions may not be provided. Although the drawing illustrates that the second anode electrode AE2 entirely (e.g., substantially entirely) covers the second metal pattern RM2, embodiments of the present disclosure are not limited thereto. The second anode electrode AE2 may be formed or provided to cover the top surface of the second metal pattern RM2.

The pixel defining layer PDL may be located or provided on the fourth insulating layer INS4 and the anode electrode AE in a portion overlapping the non-emission area NLA. The pixel defining layer PDL may cover an edge of the anode electrode AE.

In one or more embodiments, the pixel defining layer PDL may define an opening OP and may be located or provided to be around (e.g., to surround) the opening OP. The pixel defining layer PDL may expose the anode electrode AE in a portion overlapping the opening OP.

In one or more embodiments, the pixel defining layer PDL may partition the emission area EA and may separate and insulate (e.g., electrically insulate) the first anode electrode AE1 and the second anode electrode AE2.

The pixel defining layer PDL may cover a lower structure along its profile.

The pixel defining layer PDL may include an inorganic insulating (e.g., electrically insulating) material. For example, the pixel defining layer PDL may include at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

The bank structure BN may be located or provided on the pixel defining layer PDL in a portion overlapping the non-emission area NLA. The bank structure BN may serve as a separator to disconnect a portion of the light emitting element layer ELL.

The bank structure BN may include a first bank layer BN1 and a second bank layer BN2 that are sequentially stacked.

The first bank layer BN1 may be located or provided on the pixel defining layer PDL. The first bank layer BN1 may cover a lower structure along its profile.

The first bank layer BN1 may include an inorganic insulating (e.g., electrically insulating) material. For example, the first bank layer BN1 may include at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

In one or more embodiments, the first bank layer BN1 may include a material different from the pixel defining layer PDL. For example, if (e.g., when) the pixel defining layer PDL includes silicon oxide, the first bank layer BN1 may include silicon nitride.

Because the pixel defining layer PDL and the first bank layer BN1 of one or more embodiments include different materials, different etch ratios may be included in substantially the same etching process performed in the fabrication process of the display device 10. The fabrication process will be described herein in more detail.

Accordingly, the pixel defining layer PDL may have a structure that protrudes toward the emission area EA further than the first bank layer BN1. In one or more embodiments, a side surface p3 of the pixel defining layer PDL may protrude in a direction toward the emission area EA further than a first side surface a3 of the first bank layer BN1. Accordingly, the pixel defining layer PDL and the first bank layer BN1 may have a stepped portion having a stair shape (e.g., a substantially stair shape).

The second bank layer BN2 may be located or provided on the first bank layer BN1. The second bank layer BN2 may flatten the stepped portion of the lower structure.

The second bank layer BN2 may include an inorganic insulating (e.g., electrically insulating) material and may include, for example, at least one of silicon nitride (e.g., SiNₓ, wherein 0<x≤2; e.g., Si₃N₄), silicon oxide (e.g., SiOₓ, wherein 0<x≤2; e.g., SiO₂), and silicon oxynitride (e.g., SiOₓN_{y}, wherein 0<x≤2 and 0≤y≤2; e.g., SiON or Si₂N₂O).

In one or more embodiments, the second bank layer BN2 may include a material different from the material of the first bank layer BN1. In one or more embodiments, the second bank layer BN2 may include substantially the same material as the pixel defining layer PDL. For example, if (e.g., when) the pixel defining layer PDL includes silicon oxide, the first bank layer BN1 may include silicon nitride, and the second bank layer BN2 may include silicon oxide.

In one or more embodiments, because the first bank layer BN1 and the second bank layer BN2 include different materials, different etch ratios may be included in substantially the same etching process performed in the fabrication process of the display device 10. The fabrication process is described herein in more detail.

The second bank layer BN2 may include a tip tip that protrudes toward the emission area EA further than the first side surface a3 of the first bank layer BN1. The tip tip of the second bank layer BN2 may be located or provided to be around (e.g., to surround) the opening OP. An undercut may be formed or provided between the tip rip of the second bank layer BN2 and the first bank layer BN1. In one or more embodiments, the bank structure BN may have an overhang structure.

In one or more embodiments, the tip tip of the second bank layer BN2 may have a reverse tapered shape. A more detailed description thereof will be described herein.

The light emitting element layer ELL may be located or provided on the anode electrode AE. The light emitting element layer ELL may include the first light emitting element layer ELL1 overlapping the first emission area EA1 and the second light emitting element layer ELL2 overlapping the second emission area EA2. The first light emitting element layer ELL1 and the second light emitting element layer ELL2 may be spaced and/or apart (e.g., spaced apart or separated) from each other while the bank structure BN is between the first light emitting element layer ELL1 and the second light emitting element layer ELL2. In one or more embodiments, the first light emitting element layer ELL1 and the second light emitting element layer ELL2 may be separated by the bank structure BN.

The light emitting element layer ELL may completely (e.g., substantially completely) cover the anode electrode AE in a portion overlapping the emission area EA and may cover the pixel defining layer PDL in a portion overlapping the non-emission area NLA. However, according to one or more embodiments, the light emitting element layer ELL may expose a part of the pixel defining layer PDL in a portion overlapping the non-emission area NLA.

In one or more embodiments, the light emitting element layer ELL may be in contact with the first side surface a3 of the first bank layer BN1, but embodiments of the present disclosure are not limited thereto.

In one or more embodiments, in the display device 10, the second bank layer BN2 has the tip tip of that protrudes toward the emission area EA and has a reverse tapered shape, so that (e.g., such that), in the fabrication process of the display device 10, without a separate fine metal mask, the first light emitting element layer ELL1 and the second light emitting element layer ELL2 that are spaced and/or apart (e.g., spaced apart or separated) from each other in respective portions overlapping the first emission area EA1 and the second emission area EA2 may be formed or provided. The fabrication process will be described herein in more detail.

As illustrated in FIG. 6, the light emitting element layer ELL may include a plurality of light emitting stacks ST. The light emitting stack ST may include a high molecular weight organic material and/or a low molecular weight organic material that emits light of a selected (e.g., set or predetermined) color. In addition to one or more suitable organic materials, the light emitting stack ST may further include metal-containing compounds, such as organometallic compounds, inorganic materials, such as quantum dots, and/or the like. Although the drawing illustrates a three tandem structure including three light emitting stacks ST, embodiments of the present disclosure are not limited thereto. The number of light emitting stacks ST may be two or less or may be four or more.

The light emitting stack ST may include at least one light emitting layer EML. For example, the first light emitting stack ST1 may include a first light emitting layer EML1, the second light emitting stack ST2 may include a second light emitting layer EML2 overlapping the first light emitting layer EML1, and the third light emitting stack ST3 may include a third light emitting layer EML3 overlapping the first light emitting layer EML1 and the second light emitting layer EML2.

For example, the first light emitting layer EML1 may emit any one selected from among light of a first color, light of a second color, and light of a third color, the second light emitting layer EML2 may emit any one selected from among light of the first color, light of the second color, and light of the third color, and the third light emitting layer EML3 may emit any one selected from among light of the first color, light of the second color, and light of the third color. According to one or more embodiments, the first light emitting layer EML1, the second light emitting layer EML2, and the third light emitting layer EML3 may emit light of substantially the same color, or the first light emitting layer EML1, the second light emitting layer EML2, and the third light emitting layer EML3 may emit light of different colors. For example, light of the first color may be red light, light of the second color may be green light, and light of the third color may be blue light, but embodiments of the present disclosure are not limited thereto.

In yet another example, the first light emitting layer EML1 may emit a plurality of lights selected from among light of the first color, light of the second color, light of the third color, and light of a fourth color, the second light emitting layer EML2 may emit a plurality of lights selected from among light of the first color, light of the second color, light of the third color, and light of the fourth color, and the third light emitting layer EML3 may emit a plurality of lights selected from among light of the first color, light of the second color, light of the third color, and light of the fourth color. For example, light of the first color may be red light, light of the second color may be green light, light of the third color may be blue light, and light of the fourth color may be yellow light, but embodiments of the present disclosure are not limited thereto.

Each of the light emitting layers EML as described in one or more embodiments of the present disclosure may include a host and a dopant. The light emitting layer EML may be formed or provided by utilizing a phosphorescent light emitting material and/or a fluorescent light emitting material as a dopant in a host material. The host material and the dopant material are not particularly limited as long as they are the materials that are generally available or generally used.

The light emitting stack ST may further include at least one intermediate layer overlapping at least one light emitting layer EML. For example, the intermediate layer may include a hole injection layer HIL, a hole transport layer HTL, and an electron transport layer ETL. According to one or more embodiments, the hole transport layer HTL may also serve as the hole injection layer HIL.

The hole injection layer HIL may serve to facilitate the movement of holes injected from the anode electrode AE, and the hole transport layer HTL may serve to prevent the transport of holes and the introduction of electrons. One or more embodiments of the present disclosure may include any suitable materials, that are generally available or generally used, of the hole injection layer HIL and the hole transport layer HTL.

The electron transport layer ETL may serve to facilitate the transport and injection of injected electrons. The electron transport layer ETL may contain a material having high electron affinity and high electron mobility. One or more embodiments of the present disclosure may include any suitable materials, that are generally available or generally used, of the electron transport layer ETL.

A charge generation layer CGL may be located or provided between the respective light emitting stacks ST.

The charge generation layer CGL may be a functional layer that adjusts or optimizes charge balance between the respective light emitting stacks ST. Accordingly, the charge generation layer CGL may increase or enhance the luminous efficiency of the light emitting element ED and lower the driving voltage by providing charges to each of the first to third light emitting layers EML1, EML2, and EML3.

The charge generation layer CGL may include a first charge generation layer CGL1 located or provided between the first light emitting stack ST1 and the second light emitting stack ST2, and a second charge generation layer CGL2 located or provided between the second light emitting stack ST2 and the third light emitting stack ST3.

A negative charge generation layer nCGL included in the first charge generation layer CGL1 may be located or provided to be in contact with the first light emitting stack ST1 and supply electrons to the first light emitting layer EML1 and may include a host and a dopant. The host may contain an organic material, and the dopant may contain a metal material. In one or more embodiments, the negative charge generation layer nCGL may include any suitable materials, that are generally available or generally used, of the negative charge generation layer nCGL.

A positive charge generation layer pCGL included in the first charge generation layer CGL1 may be located or provided to be in contact with the second light emitting stack ST2 and supply holes to the second light emitting layer EML2 and may include a host and a dopant. The host may contain an organic material, and the dopant may contain a metal material. In one or more embodiments, the positive charge generation layer pCGL may include any suitable materials, that are generally available or generally used, of the positive charge generation layer pCGL.

The negative charge generation layer nCGL included in the second charge generation layer CGL2 may be located or provided to be in contact with the second light emitting stack ST2 and may supply electrons to the second light emitting layer EML2, and the positive charge generation layer pCGL included in the second charge generation layer CGL2 may be located or provided to be in contact with the third light emitting stack ST3 and may supply holes to the third light emitting layer EML3. Other redundant descriptions may not be provided.

In one or more embodiments, in a display device 10 applied to a high-resolution electronic device, a plurality of light emitting elements ED may be spaced and/or apart (e.g., spaced apart or separated) within a narrow area. This may indicate that a plurality of light emitting elements ED are arranged or provided to be spaced and/or apart (e.g., spaced apart or separated) at a narrow gap.

For example, if (e.g., when) a portion of the light emitting element layer ELL included in the light emitting elements ED arranged or provided at a narrow gap is formed or provided as a common layer (e.g., in a case of being entirely (e.g., substantially entirely) formed or provided in a portion overlapping the emission area EA and the non-emission area NLA), this may cause a leakage current defect in the display device 10. The leakage current defect as described in one or more embodiments may occur if (e.g., when) the current that drives at least one pixel PX among a plurality of pixels PX arranged or provided at a narrow gap leaks to a neighboring pixel PX. The leakage current defect as described in one or more embodiments may be mainly or predominantly caused through at least one of the hole injection layer HIL, the hole transport layer HTL, and the charge generation layer CGL containing a dopant material in the light emitting element layer ELL.

Accordingly, in the display device 10 of one or more embodiments, the second bank layer BN2 may be formed or provided to have a tip tip having a reverse tapered shape, so that (e.g., such that) the light emitting element layer ELL including the hole injection layer HIL, the hole transport layer HTL, and the charge generation layer CGL may be separated in each of the first emission area EA1 and the second emission area EA2. Accordingly, in the display device 10 of one or more embodiments, a leakage current defect may not occur although the light emitting elements ED are arranged or provided at a narrow gap within a narrow area.

An organic pattern ELP may be located or provided on the second bank layer BN2 in a portion overlapping the non-emission area NLA. The organic pattern ELP may overlap the tip tip of the second bank layer BN2 in the third direction DR3. The organic pattern ELP may include substantially the same material as the light emitting element layer ELL and may be spaced and/or apart (e.g., spaced apart or separated) from the light emitting element layer ELL.

As described in one or more embodiments, the process of forming or providing the light emitting element layer ELL may be performed without utilizing a separate fine metal mask. Accordingly, the material to form or provide the light emitting element layer ELL may be not only formed or provided on the anode electrode AE but also formed or provided on the second bank layer BN2. At this time, the material to form or provide the light emitting element layer ELL formed or provided on the second bank layer BN2 may be separated from the material to form or provide the light emitting element layer ELL formed or provided on the anode electrode AE, and the material to form or provide the light emitting element layer ELL formed or provided on the second bank layer BN2 may remain in the form of the organic pattern ELP. According to one or more embodiments, the organic pattern ELP may not be provided. The fabrication process will be described herein in more detail.

The cathode electrode CE may be located or provided on the light emitting element layer ELL. The cathode electrode CE may include a first cathode electrode CE1 and a second cathode electrode CE2 stacked in the third direction DR3.

In one or more embodiments, the first cathode electrode CE1 may be located or provided on the light emitting element layer ELL and may entirely (e.g., substantially entirely) cover the light emitting element layer ELL.

In one or more embodiments, the first cathode electrode CE1 may be in contact with the side surface a3 of the first bank layer BN1, but embodiments of the present disclosure are not limited thereto.

The first cathode electrode CE1 may include a transparent (e.g., substantially transparent) conductive (e.g., electrically conductive) oxide (TCO) material, such as ITO and/or IZO, and/or a semi-transmissive conductive (e.g., electrically conductive) material, such as magnesium (Mg), silver (Ag), or an alloy of magnesium (Mg) and silver (Ag).

The first cathode electrode CE1 may include a first-first cathode electrode CE11 located or provided in a portion overlapping the first emission area EA1 and a first-second cathode electrode CE12 located or provided in a portion overlapping the second emission area EA2. The first-first cathode electrode CE11 and the first-second cathode electrode CE12 may be spaced and/or apart (e.g., spaced apart or separated) from each other while the bank structure BN is between the first-first cathode electrode CE11 and the first-second cathode electrode CE12.

In one or more embodiments, the second cathode electrode CE2 may be located or provided in contact with and on the first cathode electrode CE1. In one or more embodiments, the second cathode electrode CE2 may entirely (e.g., substantially entirely) cover the tip tip of the second bank layer BN2 and may be in contact with and cover the organic pattern ELP. In one or more embodiments, the second cathode electrode CE2 may be formed or provided to overlap the emission area EA and the non-emission area NLA. The second cathode electrode CE2 may electrically connect the first-first cathode electrode CE11 and the first-second cathode electrode CE12.

The second cathode electrode CE2 may include a transparent (e.g., substantially transparent) conductive (e.g., electrically conductive) oxide (TCO) material, such as ITO and/or IZO, and/or a semi-transmissive conductive (e.g., electrically conductive) material, such as magnesium (Mg), silver (Ag), or an alloy of magnesium (Mg) and silver (Ag). In one or more embodiments, it may include only a transparent (e.g., substantially transparent) conductive (e.g., electrically conductive) oxide (TCO) material.

The encapsulation layer TFEL may be located or provided on the display element layer ECL. The encapsulation layer TFEL may prevent oxygen and/or moisture from permeating into the display element layer ECL (or reduce a degree to or occurrence of which oxygen and/or moisture permeate into the display element layer ECL) and may alleviate physical impact (or reduce a degree or occurrence of physical impact) applied to the display element layer ECL.

The encapsulation layer TFEL may include a first encapsulation layer TFE1, a second encapsulation layer TFE2, and a third encapsulation layer TFE3. The first encapsulation layer TFE1 may be located or provided on the cathode electrode CE, the second encapsulation layer TFE2 may be located or provided on the first encapsulation layer TFE1, and the third encapsulation layer TFE3 may be located or provided on the second encapsulation layer TFE2.

The first encapsulation layer TFE1 may cover the lower structure along its profile with a uniform (e.g., substantially uniform) thickness. The first encapsulation layer TFE1 may include an inorganic insulating (e.g., electrically insulating) material. For example, the first encapsulation layer TFE1 may include silicon nitride (e.g., SiNₓ, wherein 0<x≤2; e.g., Si₃N₄), silicon oxide (e.g., SiOₓ, wherein 0<x≤2; e.g., SiO₂), silicon oxynitride (e.g., SiOₓN_{y}, wherein 0<x≤2 and 0≤y≤2; e.g., SiON or Si₂N₂O), titanium oxide (e.g., TiOₓ, wherein 0<x≤2; e.g., TiO₂), aluminum oxide (e.g., AlOₓ, wherein 0<x≤2; e.g., Al₂O₃), and/or other inorganic insulating (e.g., electrically insulating) materials.

The second encapsulation layer TFE2 may flatten the stepped portion of the lower structure. The second encapsulation layer TFE2 may include an organic material. For example, the second encapsulation layer TFE2 may be an organic film made of a resin, such as an acrylic resin, an epoxy resin, a phenolic resin, a polyamide resin, a polyimide resin, and/or the like.

The third encapsulation layer TFE3 may include an inorganic insulating (e.g., electrically insulating) material. For example, the third encapsulation layer TFE3 may include silicon nitride (e.g., SiNₓ, wherein 0<x≤2; e.g., Si₃N₄), silicon oxide (e.g., SiOₓ, wherein 0<x≤2; e.g., SiO₂), silicon oxynitride (e.g., SiOₓN_{y}, wherein 0<x≤2 and 0≤y≤2; e.g., SiON or Si₂N₂O), titanium oxide (e.g., TiOₓ, wherein 0<x≤2; e.g., TiO₂), aluminum oxide (e.g., AlOₓ, wherein 0<x≤2; e.g., Al₂O₃), and/or other inorganic insulating (e.g., electrically insulating) materials.

In one or more embodiments, a color filter layer CFL may be located or provided on the encapsulation layer TFEL. The color filter layer CFL may include the first color filter CF1 and the second color filter CF2.

In one or more embodiments, the first color filter CF1 may be located or provided in a portion overlapping the first emission area EA1. The first color filter CF1 may transmit light of the first color (e.g., light in a red wavelength band). Accordingly, the first color filter CF1 may transmit light of the first color among light emitted from the first light emitting element ED1.

In one or more embodiments, the first color filter CF1 may transmit light of the third color (e.g., light in a blue wavelength band). In this case, the first color filter CF1 may transmit light of the third color among light emitted from the first light emitting element ED1.

In one or more embodiments, the second color filter CF2 may be located or provided in a portion overlapping the second emission area EA2. The second color filter CF2 may transmit light of the second color (e.g., light in a green wavelength band). Accordingly, the second color filter CF2 may transmit light of the second color among light emitted from the second light emitting element ED2.

Accordingly, at least one of light of the first color (e.g., red light) and light of the third color (e.g., blue light) may be emitted from the first emission area EA1, and light of the second color (e.g., green light) may be emitted from the second emission area EA2.

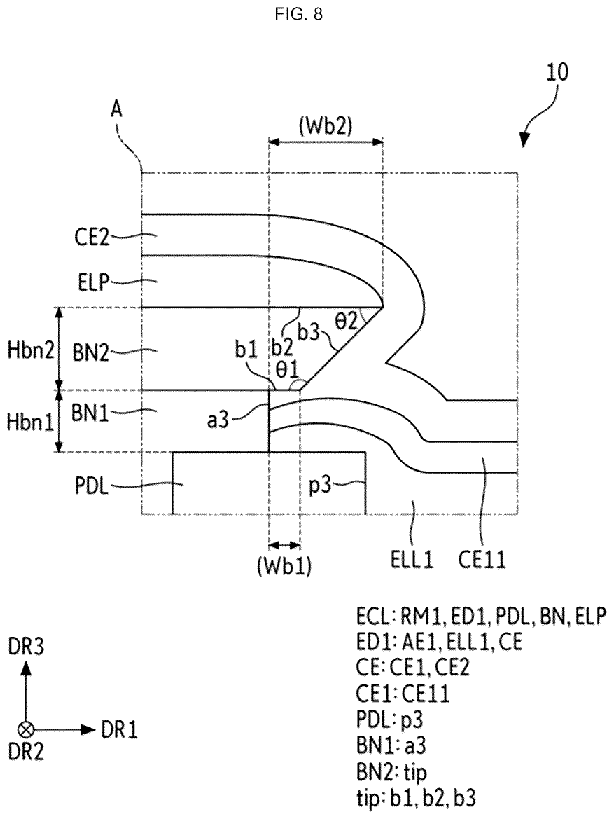

FIG. 8 is an enlarged cross-sectional view of the area ‘A’ of FIG. 7.

Referring to FIG. 8 in addition to FIGS. 1 to 7, in one or more embodiments, the first bank layer BN1 may include a first thickness Hbn1, and the tip tip of the second bank layer BN2 may include a second thickness Hbn2. The meaning of the thickness as described in one or more embodiments is a length in the third direction DR3 (z-axis direction) in cross-sectional view and may have substantially the same meaning as the height.

In one or more embodiments, the first thickness Hbn1 of the first bank layer BN1 may be less than or equal to the second thickness Hbn2 of the tip tip of the second bank layer BN2. In one or more embodiments, the second thickness Hbn2 of the tip tip of the second bank layer BN2 may be greater than or equal to the first thickness Hbn1 of the first bank layer BN1.

The display device 10 of one or more embodiments may be formed or provided such that the light emitting element layer ELL and the organic pattern ELP are spaced and/or apart (e.g., spaced apart or separated) from each other without being in contact with each other, by forming or providing the second thickness Hbn2 of the tip tip of the second bank layer BN2 to be greater than or equal to the first thickness Hbn1 of the first bank layer BN1.

In one or more embodiments, the tip tip of the second bank layer BN2 may include a first surface b1, a second surface b2, and a side surface b3. The first surface b1 may be one surface being opposite to (e.g., facing) the first bank layer BN1, the second surface b2 may be one surface being opposite to (e.g., facing) the first surface b1, and the side surface b3 may be one surface connecting the first surface b1 and the second surface b2 to each other.

In one or more embodiments, a width Wb2 of the second surface b2 may be greater than a width Wb1 of the first surface b1. The meaning of the width as described in one or more embodiments refers to a length in the first direction DR1 (x-axis direction) in cross-sectional view and may have substantially the same meaning as width.

In one or more embodiments, the first surface b1 and the side surface b3 included in the tip tip of the second bank layer BN2 may form or provide a first inclination angle θ1, and the first inclination angle θ1 may be an obtuse angle. For example, the first inclination angle θ1 may have a value greater than or equal to 130 degrees.

In one or more embodiments, the second surface b2 and the side surface b3 included in the tip tip of the second bank layer BN2 may form or provide a second inclination angle θ2, and the second inclination angle θ2 may be an acute angle. For example, the second inclination angle θ2 may have a value less than or equal to 50 degrees.

For example, if (e.g., when) the second inclination angle θ2 includes an angle greater than 50 degrees, in the fabrication process of the display device 10, the material to form or provide the light emitting element layer ELL may be formed or provided on the side surface b3 of the second bank layer BN2 and/or the first surface b1 of the second bank layer BN2. Accordingly, the first light emitting element layer ELL1 and the second light emitting element layer ELL2 may be connected without being spaced and/or apart (e.g., spaced apart or separated), so that (e.g., such that) a leakage current defect in the display device 10 may occur.

In one or more embodiments, the value of the width Wb2 of the second surface b2 of the second bank layer BN2 may be greater than the value of the first thickness Hbn1 of the first bank layer BN1. The width Wb2 of the second surface b2 may be defined as the width of the tip tip of the second bank layer BN2. In one or more embodiments, the value of the width Wb2 of the tip tip of the second bank layer BN2 may be greater than the value of the first thickness Hbn1 of the first bank layer BN1.

For example, if (e.g., when) the value of the width Wb2 of the tip tip of the second bank layer BN2 is formed or provided to be smaller than the value of the first thickness Hbn1 of the first bank layer BN1, in the fabrication process of the display device 10, the material to form or provide the light emitting element layer ELL may be formed or provided on the side surface b3 of the second bank layer BN2 and/or the first surface b1 of the second bank layer BN2. Accordingly, the first light emitting element layer ELL1 and the second light emitting element layer ELL2 may be connected without being spaced and/or apart (e.g., spaced apart or separated), and a leakage current defect in the display device 10 may occur.

Accordingly, the second thickness Hbn2 of the tip tip of the second bank layer BN2 may be formed or provided to be greater than or equal to the first thickness Hbn1 of the first bank layer BN1, the second inclination angle θ2 may be formed or provided in the range of 50 degrees or less, and the value of the width Wb2 of the tip tip of the second bank layer BN2 may be formed or provided to be larger than the value of the first thickness Hbn1 of the first bank layer BN1, which may be major factors in solving the leakage current defect (or in reducing a degree or occurrence of the leakage current defect) of the display device 10.

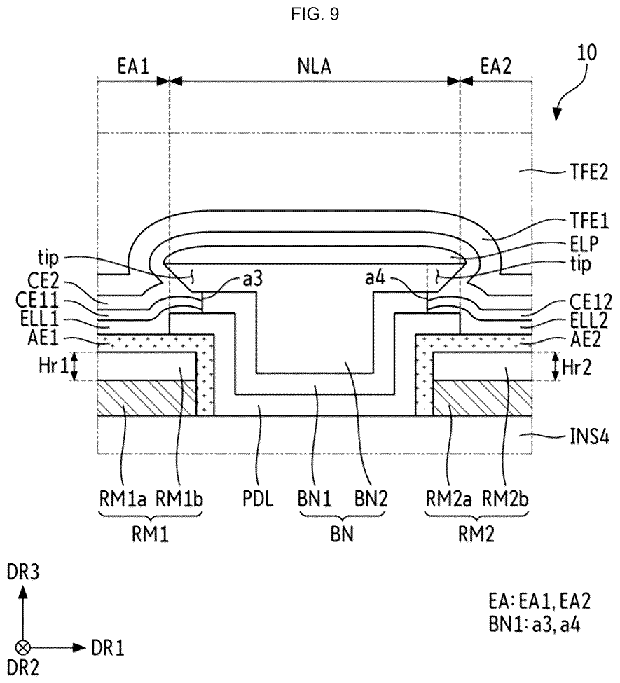

FIG. 9 is an enlarged cross-sectional view of a display element layer overlapping a non-emission area located or provided between the first emission area and the second emission area in FIG. 5.

Referring to FIG. 9 in addition to FIGS. 1 to 8, the first anode electrode AE1 may be located or provided in contact with and on the first metal pattern RM1 in a portion overlapping the first emission area EA1, and the second anode electrode AE2 may be located or provided in contact with and on the second metal pattern RM2 in a portion overlapping the second emission area EA2.

As described in one or more embodiments, the first insulating layer RM1b and the second insulating layer RM2b may have different thicknesses. For example, the first insulating layer RM1b may have a first thickness Hr1, and the second insulating layer RM2b may have a second thickness Hr2. The meaning of the thickness as described in one or more embodiments refers to a length in the third direction DR3 in cross-sectional view and may be utilized with substantially the same meaning as height.

In one or more embodiments, the second thickness Hr2 may be greater than the first thickness Hr1. Accordingly, the first anode electrode AE1 and the second anode electrode AE2 may be located or provided at different heights. For example, the first anode electrode AE1 may be located or provided at a different position in the third direction DR3 from the second anode electrode AE2.

In one or more embodiments, the first anode electrode AE1 may be located or provided closer to the substrate SUB than the second anode electrode AE2, and the second anode electrode AE2 may be located or provided farther from the substrate SUB than the first anode electrode AE1. This may be caused by a difference in thickness between the first insulating layer RM1b of the first metal pattern RM1 and the second insulating layer RM2b of the second metal pattern RM2 as described in one or more embodiments.

In one or more embodiments, the distance between the first anode electrode AE1 and a first reflective electrode RM1a may be located or provided closer than the distance between the second anode electrode AE2 and a second reflective electrode RM2a.

The display device 10 of one or more embodiments may increase or enhance and/or optimize the micro-cavity (or thin film cavity) effect of each of the first light emitting element ED1 and the second light emitting element ED2 by forming or providing the distance between the first anode electrode AE1 and the first reflective electrode RM1a and the distance between the second anode electrode AE2 and the second reflective electrode RM2a differently.

In one or more embodiments, the pixel defining layer PDL may be in contact with and cover an edge of the first anode electrode AE1 and, at the same time (e.g., concurrently or simultaneously), may be in contact with and cover an edge of the second anode electrode AE2. The pixel defining layer PDL in contact with the first anode electrode AE1 and the pixel defining layer PDL in contact with the second anode electrode AE2 may be extended. The pixel defining layer PDL may include a stepped portion in a portion overlapping the non-emission area NLA.

In one or more embodiments, the first bank layer BN1 may include the first side surface a3 being opposite to (e.g., facing) the first emission area EA1 and a second side surface a4 being opposite to (e.g., facing) the second emission area EA2. The first side surface a3 and the second side surface a4 may be surfaces being opposite to (e.g., facing) each other.

The first bank layer BN1 may include a stepped portion in a portion overlapping the non-emission area NLA.

The first light emitting element layer ELL1 and the first-first cathode electrode CE11 may be in contact with the first side surface a3 of the first bank layer BN1, and the second light emitting element layer ELL2 and the first-second cathode electrode CE12 may be in contact with the second side surface a4, but embodiments of the present disclosure are not limited thereto.

In one or more embodiments, because the first bank layer BN1 includes an inorganic insulating (e.g., electrically insulating) material, the first-first cathode electrode CE11 and the first-second cathode electrode CE12 may be separated and insulated (e.g., electrically insulated) by the first bank layer BN1. The first-first cathode electrode CE11 and the first-second cathode electrode CE12 that are spaced and/or apart (e.g., spaced apart or separated) from each other may be electrically connected by the second cathode electrode CE2. Redundant descriptions may not be provided.

The tip tip of the second bank layer BN2 may protrude in opposite directions toward the emission area EA further than the first side surface a3 and the second side surface a4 of the first bank layer BN1. The second bank layer BN2 may flatten the stepped portion of the first bank layer BN1. The fabrication process will be described herein in more detail.

Other redundant descriptions may not be provided.

Referring again to FIGS. 1 to 9, in the display device 10 of one or more embodiments, the light emitting element layer ELL including the hole injection layer HIL, the hole transport layer HTL, and the charge generation layer CGL may be separated in a portion overlapping each of the first emission area EA1 and the second emission area EA2 by utilizing the bank structure BN, so that (e.g., such that) the leakage current defect of the display device 10 may be solved (or a degree or occurrence of the leakage current defect of the display device 10 may be reduced). Redundant descriptions may not be provided.

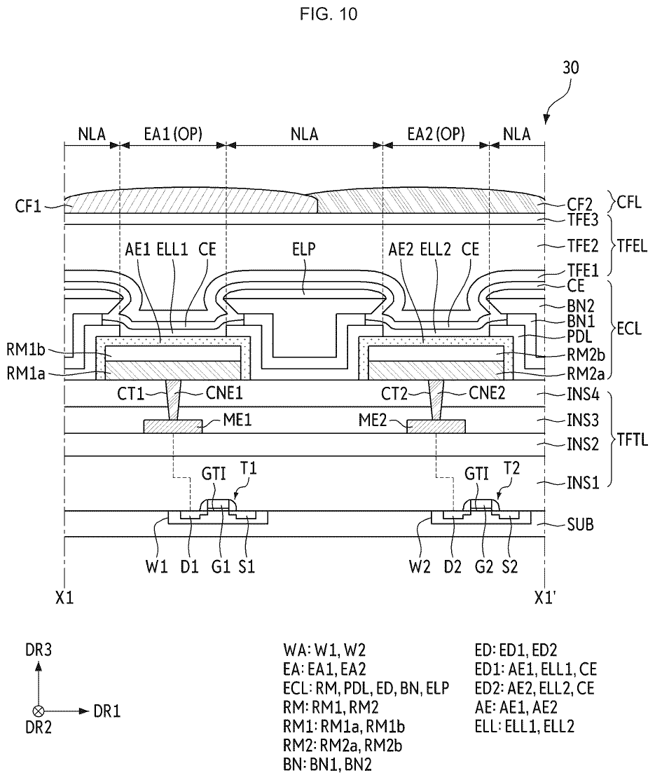

FIG. 10 is a cross-sectional view of a display device according to one or more embodiments, taken along the line X1-X1′ of FIG. 4.

Referring to FIG. 10 in addition to FIGS. 1 to 9, the display element layer ECL included in a display device 30 of one or more embodiments may have a different structure from the display element layer ECL included in the display device 10. Hereinafter, one or more features of the display device 10 and the display device 30 that are redundant may not be provided, and different structures are described herein in more detail.

The display element layer ECL of the display device 30 may include the metal pattern RM, the pixel defining layer PDL, the light emitting element ED, the bank structure BN, and an organic pattern ELP, and the pixel defining layer PDL, the light emitting element ED, the bank structure BN, and the organic pattern ELP included in the display device 30 may have substantially the same structure and features as the pixel defining layer PDL, the light emitting element ED, the bank structure BN, and the organic pattern ELP included in the display device 10. Redundant descriptions may not be provided.

The light emitting element ED included in the display element layer ECL may include the first light emitting element ED1 and the second light emitting element ED2. The first light emitting element ED1 may include a first anode electrode AE1, a first light emitting element layer ELL1, and a cathode electrode CE, and the second light emitting element ED2 may include a second anode electrode AE2, a second light emitting element layer ELL2, and a cathode electrode CE.

The cathode electrode CE included in the display device 30 may be integrally formed or provided in a portion overlapping the emission area EA and the non-emission area NLA and may be a common electrode. The cathode electrode CE included in the display device 30 may be located or provided in contact with and on the first light emitting element layer ELL1 and the second light emitting element layer ELL2 in a portion overlapping the emission area EA and may entirely (e.g., substantially entirely) cover the organic pattern ELP in a portion overlapping the non-emission area NLA. According to one or more embodiments, the cathode electrode CE included in the display device 30 may include a plurality of layers.

The cathode electrode CE may include a metal layer having a low work function and may further include a transparent (e.g., substantially transparent) metal oxide layer according to one or more embodiments. For example, the cathode electrode CE may include a material layer having a low work function, such as Li, Ca, LiF, Al, Mg, Ag, Pt, Pd, Ni, Au Nd, Ir, Cr, BaF, Ba, or a compound or mixture thereof (e.g., a mixture of Ag and Mg) and multiple-layer such as LiF/Ca, LiF/Al. Other redundant descriptions may not be provided.

The first light emitting element layer ELL1 and the second light emitting element layer ELL2 included in the display device 30 of one or more embodiments may be spaced and/or apart (e.g., spaced apart or separated) from each other while the bank structure BN is between the first light emitting element layer ELL1 and the second light emitting element layer ELL2. The first light emitting element layer ELL1 and the second light emitting element layer ELL2 included in the display device 30 may be formed or provided to be spaced and/or apart (e.g., spaced apart or separated) from each other without a separate fine metal mask during the fabrication process, because the second bank layer BN2 included in the bank structure BN has a reverse tapered shape.

In the display device 30 of one or more embodiments, the light emitting element layer ELL including the hole injection layer HIL, the hole transport layer HTL, and the charge generation layer CGL may be separated in a portion overlapping each of the first emission area EA1 and the second emission area EA2 by utilizing the bank structure BN, so that (e.g., such that) the leakage current defect of the display device 30 may be solved (or a degree or occurrence of the leakage current defect of the display device 30 may be reduced). Redundant descriptions may not be provided.

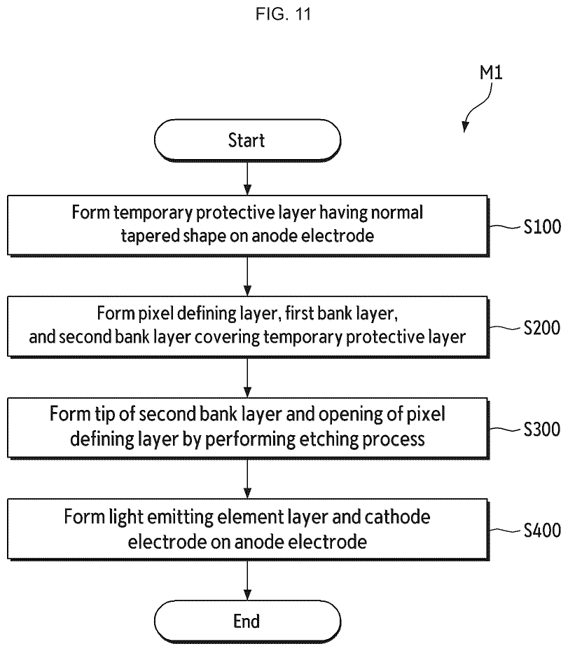

FIG. 11 is a flowchart illustrating a method for fabricating the display element layer in FIG. 5.

Referring to FIG. 11, a method M1 for fabricating the display device 10 according to one or more embodiments may include forming or providing a temporary protective layer having a normal tapered shape on an anode electrode (the method (e.g., step) S100), forming or providing a pixel defining layer, a first bank layer, and a second bank layer that cover the temporary protective layer (the method (e.g., step) S200), forming or providing a tip of the second bank layer and an opening of the pixel defining layer by performing an etching process (the method (e.g., step) S300), and forming or providing a light emitting element layer and a cathode electrode on the anode electrode (the method (e.g., step) S400).

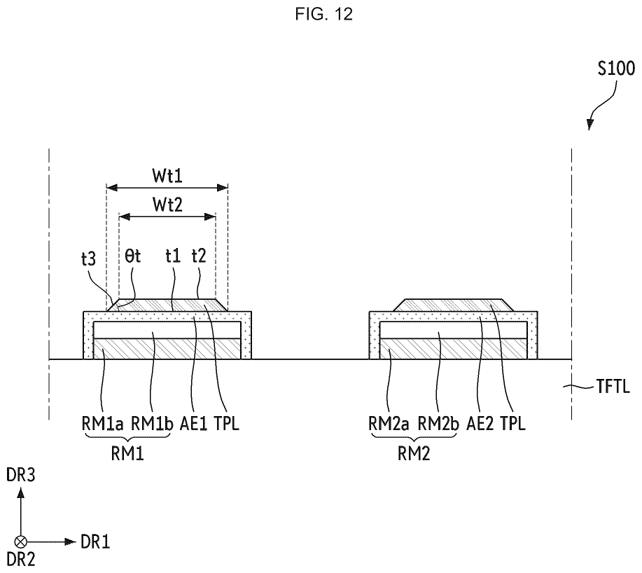

FIG. 12 is a cross-sectional view illustrating the method (e.g., step) S100 of FIG. 11.

Referring to FIG. 12, the method (e.g., step) S100 of forming or providing a temporary protective layer having a normal tapered shape on an anode electrode is described.

First, the first anode electrode AE1 covering the first metal pattern RM1 and the second anode electrode AE2 covering the second metal pattern RM2 may be formed or provided on the transistor layer TFTL. The first anode electrode AE1 may be formed or provided in contact with and on the first metal pattern RM1, and the second anode electrode AE2 may be formed or provided in contact with and on the second metal pattern RM2. In the present process, the structures of the transistor layer TFTL, the first metal pattern RM1, and the second metal pattern RM2 may be substantially the same as described in one or more embodiments with reference to FIG. 5. Redundant descriptions may not be provided.

In the present process, the thicknesses of the first insulating layer RM1b and the second insulating layer RM2b may be differently formed or provided. Redundant descriptions may not be provided.

In the present process, a temporary protective layer TPL may be located or provided in contact with and on the top surface of the anode electrode AE. The temporary protective layer TPL may be in contact with and cover a portion of the top surface of the anode electrode AE, and thus may protect the anode electrode AE from damage during a subsequent etching process.

The temporary protective layer TPL may include at least one of a transparent (e.g., substantially transparent) conductive (e.g., electrically conductive) oxide (TCO) material and an inorganic insulating (e.g., electrically insulating) material.

In the present process, the temporary protective layer TPL may have a normal tapered shape. For example, a width Wt1 of a bottom surface t1 of the temporary protective layer TPL may be greater (larger) than a width Wt2 of a top surface t2, and an inclination angle θt formed by (e.g., between) the bottom surface t1 and a side surface t3 may be an acute angle. For example, the inclination angle θt may be less than or equal to 50 degrees.

In the present process, the temporary protective layer TPL may have a normal tapered shape, and thus may assist the second bank layer BN2 to have a reverse tapered shape in a subsequent process. A more detailed description thereof will be described herein.

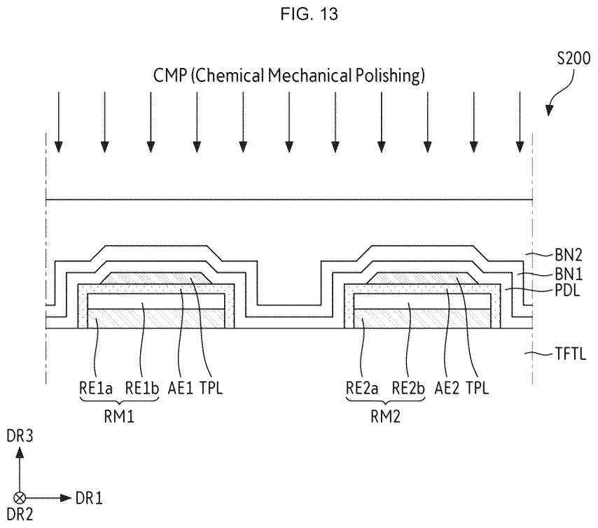

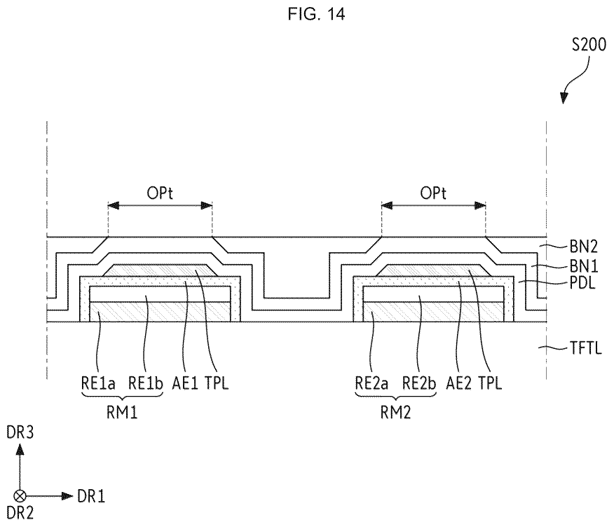

FIGS. 13 and 14 are cross-sectional views illustrating the method (e.g., step) S200 of FIG. 11.

Referring to FIGS. 13 and 14, the method (e.g., step) S200 of forming or providing a pixel defining layer, a first bank layer, and a second bank layer that cover a temporary protective layer is described.

First, the pixel defining layer PDL may be formed or provided on the temporary protective layer TPL. The pixel defining layer PDL may entirely (e.g., substantially entirely) cover the temporary protective layer TPL and the anode electrode AE.

The pixel defining layer PDL may be formed or provided through a film forming or providing process of an insulating (e.g., electrically insulating) film by utilizing at least one insulating (e.g., electrically insulating) material (e.g., an inorganic insulating (e.g., electrically insulating) material) as described in one or more embodiments. The material and/or method of forming or providing the pixel defining layer PDL may be suitably changed depending on embodiments.

In the present process, the pixel defining layer PDL may cover a lower structure along its profile. Accordingly, in a portion overlapping the temporary protective layer TPL, the pixel defining layer PDL may include a stepped portion having a normal tapered shape.

In one or more embodiments, the pixel defining layer PDL may cover the stepped portion formed or provided by the first anode electrode AE1, the second anode electrode AE2, and the transistor layer TFTL. Accordingly, the pixel defining layer PDL may include a stepped portion in an overlapping portion between the first anode electrode AE1 and the second anode electrode AE2.

Subsequently, the first bank layer BN1 may be formed or provided on the pixel defining layer PDL. The first bank layer BN1 may entirely (e.g., substantially entirely) cover the pixel defining layer PDL.

The first bank layer BN1 may be formed or provided through a film forming or providing process of an insulating (e.g., electrically insulating) film by utilizing at least one insulating (e.g., electrically insulating) material (e.g., an inorganic insulating (e.g., electrically insulating) material) as described in one or more embodiments. The material and/or method of forming or providing the first bank layer BN1 may be suitably changed depending on embodiments.

In the present process, the first bank layer BN1 may cover a lower structure along its profile. Accordingly, in a portion overlapping the temporary protective layer TPL, the first bank layer BN1 may include a stepped portion having a normal tapered shape.

In one or more embodiments, the first bank layer BN1 may cover the stepped portion of the pixel defining layer PDL. Accordingly, the first bank layer BN1 may include a stepped portion in an overlapping portion between the first anode electrode AE1 and the second anode electrode AE2.

Next, the second bank layer BN2 may be formed or provided on the first bank layer BN1. The second bank layer BN2 may be formed or provided to have a thickness capable of flattening the stepped portion formed or provided by the first bank layer BN1.

In the present process, the second bank layer BN2 may be formed or provided through a film forming or providing process utilizing a tetraethyl orthosilicate (TEOS) material. However, embodiments of the present disclosure are not limited thereto, and the material and/or method of forming or providing the second bank layer BN2 may be suitably changed depending on embodiments.

In the present process, the second bank layer BN2 may include a stepped portion having a normal tapered shape in a portion overlapping the temporary protective layer TPL.

Subsequently, a chemical mechanical polishing (CMP) process may be performed.

In the present process, the first bank layer BN1 may function as an etch stopper. Accordingly, the chemical mechanical polishing (CMP) process may be performed up to a point at which one surface of the first bank layer BN1 is exposed. In one or more embodiments, in the present process, a portion of the second bank layer BN2 may be removed, and the remaining second bank layer BN2 may define a temporary opening OPt. The second bank layer BN2 may expose the first bank layer BN1 in a portion overlapping the temporary opening OPt, and the second bank layer BN2 may be located or provided to be around (e.g., to surround) the temporary opening OPt.

In a portion that does not overlap the temporary opening OPt, the second bank layer BN2 may flatten the stepped portion formed or provided by the first bank layer BN1.

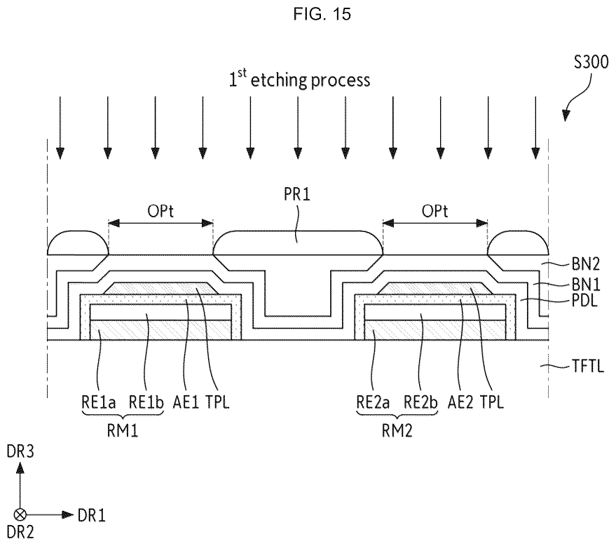

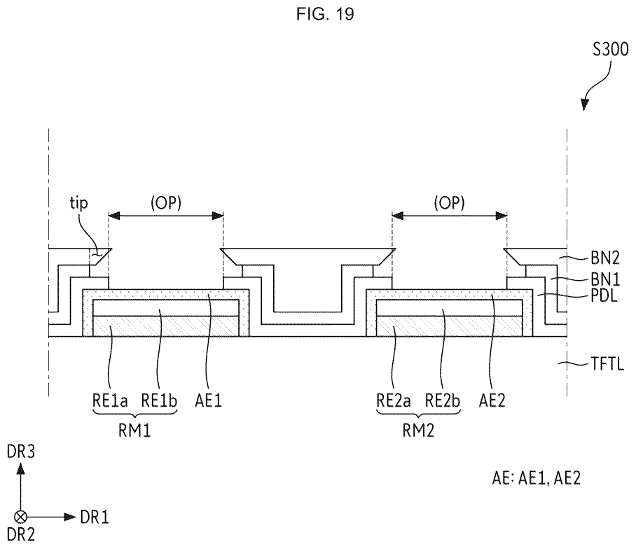

FIGS. 15 to 19 are cross-sectional views illustrating the method (e.g., step) S300 of FIG. 11.

Referring to FIGS. 15 to 19, the method (e.g., step) S300 of performing an etching process to form or provide the tip of the second bank layer and the opening of the pixel defining layer is described.

First, a photoresist PR1 may be formed or provided on the second bank layer BN2 in a portion that does not overlap the temporary opening OPt. In the present process, a plurality of photoresists PR1 may be formed or provided, and the plurality of photoresists PR1 may be spaced and/or apart (e.g., spaced apart or separated) from each other.

Subsequently, a first etching process (1^{st} etching process) may be performed. For example, the first etching process may be performed as a dry etching process.

For example, the dry etching process may include a reactive ion etching (RIE) process utilizing a reaction gas, such as CHF₃, CH₃F, CH₂F₂, CHF₆, CF₄, C₂F₆, C₃F₆, and/or the like, and/or a sputtering gas, such as Ar, O₂/Ar, and/or the like. In this case, an inductively coupled plasma (ICP) source and/or a capacitively coupled plasma (CCP) source may be utilized as a plasma source.

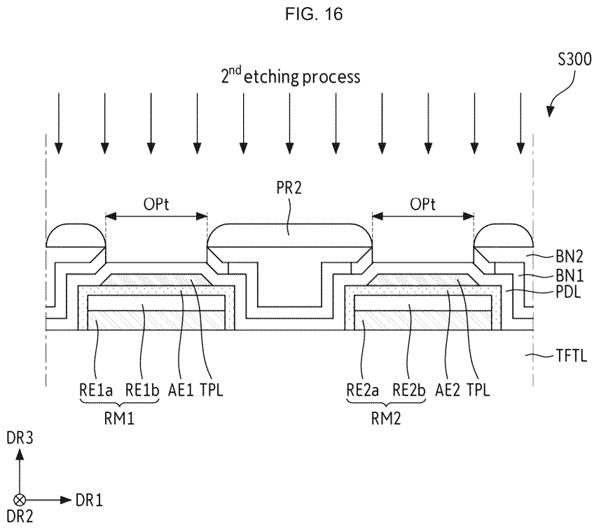

In the present process, the first bank layer BN1 that does not overlap the photoresist PR1 may be removed, and a portion of the pixel defining layer PDL may be exposed in a portion overlapping the temporary opening OPt, as illustrated in FIG. 16.

Next, a photoresist PR2 may be formed or provided on the second bank layer BN2 in a portion that does not overlap the temporary opening OPt. In the present process, a plurality of photoresists PR2 may be formed or provided, and the plurality of photoresists PR2 may be spaced and/or apart (e.g., spaced apart or separated) from each other.

Subsequently, a second etching process (2^{nd} etching process) may be performed. For example, the second etching process may be performed as a wet etching process.

For example, the wet etching process may be performed utilizing a liquid chemical solution, such as a diluted hydrofluoric acid solution, a nitric acid solution, a tetramethylammonium hydroxide solution, a potassium hydroxide solution, and/or the like.

In the present process, the first bank layer BN1 and the second bank layer BN2 may have different etch ratios for substantially the same etching solution. For example, the first bank layer BN1 may have a higher etching rate than the second bank layer BN2.

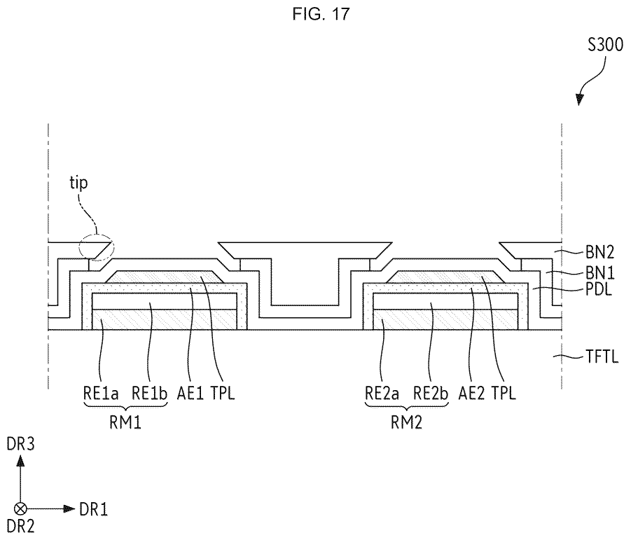

Accordingly, as illustrated in FIG. 17, the second bank layer BN2 may have a tip tip that protrudes in the first direction DR1 further than the side surface of the first bank layer BN1.

In the present process, the tip tip of the second bank layer BN2 may have a reverse tapered shape. The reverse tapered shape of the tip tip may be formed or provided if (e.g., when) the second bank layer BN2 covers the temporary protective layer TPL having a normal tapered shape along its shape. The more detailed structure of the tip tip of the second bank layer BN2 may be substantially the same as described in FIG. 8. Redundant descriptions may not be provided.

The display device 10 of one or more embodiments may include a temporary protective layer TPL having a normal tapered shape in the fabrication process, so that (e.g., such that) the tip tip of the second bank layer BN2 having a reverse tapered shape may be formed or provided without separate physical processing. Accordingly, the display device 10 of one or more embodiments may have ease of fabrication.

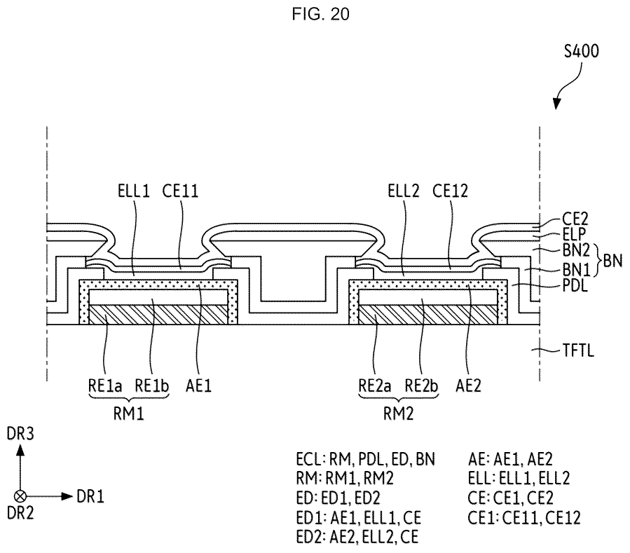

The tip tip of the second bank layer BN2 may assist in spacing the first light emitting element layer ELL1 and the second light emitting element layer ELL2 apart during the process of forming or providing the subsequent light emitting element layer ELL (see FIG. 20). Redundant descriptions may not be provided.

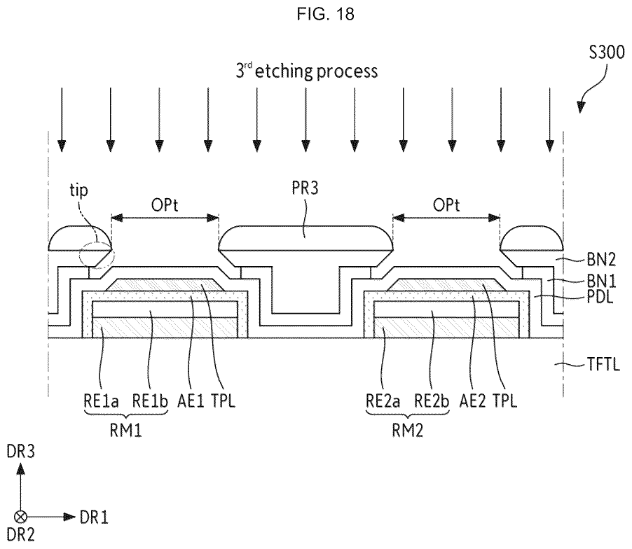

Next, referring to FIG. 18, a photoresist PR3 may be formed or provided on the second bank layer BN2 in a portion that does not overlap the temporary opening OPt. In the present process, a plurality of photoresists PR3 may be formed or provided, and the plurality of photoresists PR3 may be spaced and/or apart (e.g., spaced apart or separated) from each other.

Subsequently, a third etching process (3^{rd} etching process) may be performed. For example, the third etching process may include at least one of a dry etching process and a wet etching process. The third etching process may be performed in one or more suitable methods depending on the materials contained in the pixel defining layer PDL and the temporary protective layer TPL.

For example, if (e.g., when) the temporary protective layer TPL includes an inorganic insulating (e.g., electrically insulating) material, the present process may be performed as a dry etching process, and the pixel defining layer PDL and the temporary protective layer TPL may be removed in substantially the same process.

For example, if (e.g., when) the temporary protective layer TPL includes a metal material, the present process may be performed by alternately performing a dry etching process and a wet etching process, and after the pixel defining layer PDL is removed first, the temporary protective layer TPL may be removed.

In the present process, the pixel defining layer PDL that does not overlap the photoresist PR3 may be removed, so that (e.g., such that) the pixel defining layer PDL may define the opening OP. In a portion overlapping the opening OP, the temporary protective layer TPL may be all removed, and the anode electrode AE may be exposed. The pixel defining layer PDL may be located or provided to cover the edge of the anode electrode AE.

The pixel defining layer PDL may have a structure that protrudes in the first direction DR1 further than the first bank layer BN1. Redundant descriptions may not be provided.

FIG. 20 is a cross-sectional view illustrating the method (e.g., step) S400 of FIG. 11.

Referring to FIG. 20, the method (e.g., step) S400 of forming or providing a light emitting element layer and a cathode electrode on an anode electrode is described in more detail.

First, the light emitting element layer ELL may be formed or provided on the anode electrode AE.

In the present process, the light emitting element layer ELL may be formed or provided through a deposition process utilizing an open mask. The display device 10 of one or more embodiments may include the tip tip of the second bank layer BN2 having a reverse tapered shape, so that (e.g., such that) the first light emitting element layer ELL1 and the second light emitting element layer ELL2 that are respectively spaced and/or apart (e.g., spaced apart or separated) on the first anode electrode AE1 and the second anode electrode AE2 may be formed or provided without utilizing a separate fine metal mask. Accordingly, the display device 10 of one or more embodiments may have ease of fabrication.

Subsequently, the cathode electrode CE may be formed or provided on the light emitting element layer ELL.

In the present process, the cathode electrode CE may be formed or provided through a deposition process utilizing an open mask. The process of forming or providing the cathode electrode CE may have a higher step coverage than the process of forming or providing the light emitting element layer ELL. Accordingly, the cathode electrode CE may entirely (e.g., substantially entirely) cover the light emitting element layer ELL.

In one or more embodiments, the cathode electrode CE may include the first cathode electrode CE1 and the second cathode electrode CE2. The first cathode electrode CE1 may include the first-first cathode electrode CE11 located or provided on the first light emitting element layer ELL1 and the first-second cathode electrode CE12 located or provided on the second light emitting element layer ELL2. The first-first cathode electrode CE11 and the first-second cathode electrode CE12 may be spaced and/or apart (e.g., spaced apart or separated) from each other while the bank structure BN is between the first-first cathode electrode CE11 and the first-second cathode electrode CE12. The second cathode electrode CE2 may be entirely (e.g., substantially entirely) formed or provided on the light emitting element layer ELL and may electrically connect the first-first cathode electrode CE11 and the first-second cathode electrode CE12. The second cathode electrode CE2 may be a common layer and a common electrode.

In this way, the display element layer ECL illustrated in FIG. 5 may be fabricated.

Referring again to FIGS. 1 to 20, the display device 10 of one or more embodiments may include the first light emitting element layer ELL1 and the second light emitting element layer ELL2 that are respective spaced and/or apart (e.g., spaced apart or separated) in portions overlapping the first emission area EA1 and the second emission area EA2 by utilizing the tip tip of the second bank layer BN2 having a reverse tapered shape, so that (e.g., such that) a reliability problem of the display device 10 caused by leakage current may be solved.

In one or more embodiments, the display device 10 of one or more embodiments may solve the problem of damage to the anode electrode AE caused during the fabrication process by including the temporary protective layer TPL on the anode electrode AE during the fabrication process.

In one or more embodiments, the display device 10 of one or more embodiments may include the tip tip of the second bank layer BN2 having a reverse tapered shape without separate physical processing by including the temporary protective layer TPL having a normal tapered shape in the fabrication process. Accordingly, the display device 10 of one or more embodiments may have ease of fabrication.

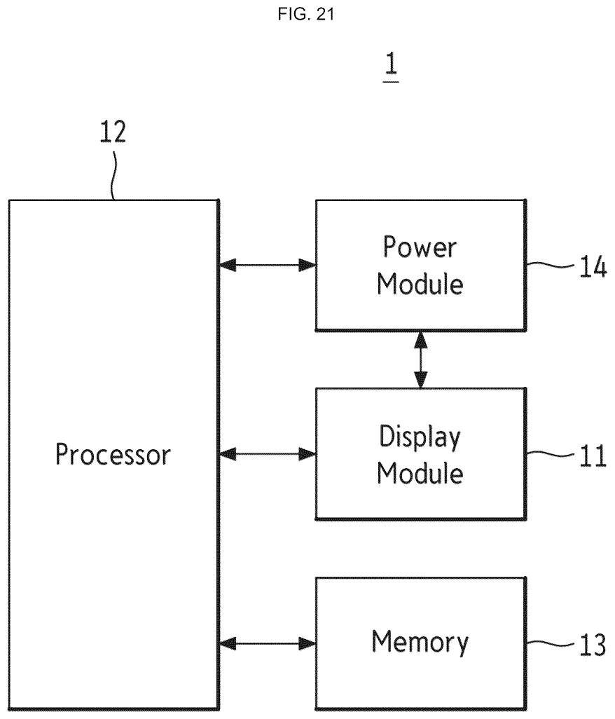

FIG. 21 is a block diagram of an electronic device according to one or more embodiments.

Referring to FIG. 21 in addition to FIGS. 1 to 20, the display device 10 or 30 according to one or more embodiments may be applied to one or more suitable electronic devices 1. The electronic device 1 according to one or more embodiments may include the display device 10 or 30 as described in one or more embodiments and may further include, in addition to the display device 10 or 30, a module or device having other additional functions.

The electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information required or desired for the operation of the processor 12 or the display module 11. If (e.g., when) the processor 12 executes an application stored in the memory 15, an image data signal and/or an input control signal may be transmitted to the display module 11, and the display module 11 may process the received signal and output image information through a display screen.

The power module 14 may include a power supply module, such as a power adapter and/or a battery device, and a power conversion module that converts power supplied by the power supply module to generate power required or desired for the operation of the electronic device 1.

At least one selected from among the components of the electronic device 1 as described in one or more embodiments may be included in the display device 10 or 30 as described in one or more embodiments. Further, one or more of individual modules functionally included in one module may be included in the display device 10 or 30 and one or more of others may be provided separately from the display device 10 or 30. For example, the display device 10 or 30 may include the display module 11, and the processor 12, the memory 13, and the power module 14 may be provided in the form of other devices in the electronic device 1 other than the display device 10 or 30.

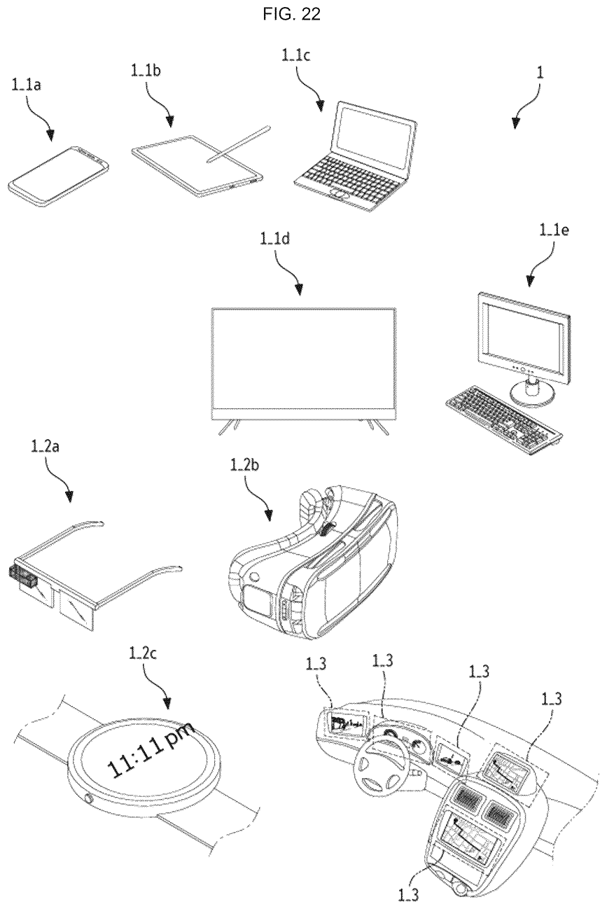

FIG. 22 is schematic views of electronic devices according to one or more embodiments.

Referring to FIG. 22 in addition to FIGS. 1 to 21, one or more suitable electronic devices 1 to which the display device 10 or 30 according to one or more embodiments are applied may include not only an image display electronic device, such as a smartphone 1_1a, a tablet PC 1_1b, a laptop 1_1c, a TV 1_1d, and/or a desk monitor 1_1e, but also a wearable electronic device including a display module, such as smart glasses 1_2a, a head mounted display 1_2b, and/or a smart watch 1_2c, and/or a vehicle electronic device 1_3 including a display module, such as a room mirror display, a center information display (CID) placed on a dashboard, a center fascia, and/or an instrument panel of a car.

In concluding the detailed description, those skilled in the art will appreciate that one or more suitable variations and modifications may be made to the embodiments without substantially departing from the spirit and scope of the present disclosure. Therefore, the disclosed embodiments of the present disclosure are used in a generic and descriptive sense only and not for purposes of limitation.

The scope of the present disclosure is represented by the scope of the appended claims and equivalents thereof, rather than the detailed description. All changes or modifications derived from the meaning and scope of the claims and equivalents thereof should be interpreted as being included in the scope of the present disclosure.

Although one or more embodiments of the present disclosure have been described with reference to the accompanying drawings, it will be apparent to those skilled in the art that the present disclosure can be embodied in one or more suitable forms without departing from the spirit and cope of the present disclosure. Thus, the embodiments as described herein are to be considered in all respects as illustrative and not restrictive.

The aspects and features of one or more embodiments of the present disclosure may be combined partially or totally. As will be clearly appreciated by those skilled in the art, one or more suitable interactions and operations may be feasible. Also, one or more embodiments may be practiced individually or in combination.

What is claimed is:

1. A display device comprising:
a substrate comprising an emission area and a non-emission area;
an anode electrode on the emission area of the substrate;
a pixel defining layer provided on the non-emission area of the substrate and covering an edge of the anode electrode;
a bank structure comprising a first bank layer on the pixel defining layer and a second bank layer having a tip protruding toward the emission area further than a side surface of the first bank layer; and
a light emitting element layer provided on the anode electrode and comprising a first light emitting element layer and a second light emitting element layer that are spaced apart from each other while the bank structure is between the first light emitting element layer and the second light emitting element layer,
wherein the tip of the second bank layer has a reverse tapered shape, and
a thickness of the tip of the second bank layer is greater than or equal to a thickness of the first bank layer.

2. The display device as claimed in claim 1, wherein the first bank layer and the second bank layer contain an inorganic insulating material.

3. The display device as claimed in claim 2, wherein the first bank layer and the second bank layer contain different materials.

4. The display device as claimed in claim 1, wherein the tip of the second bank layer comprises a first surface being opposite to the first bank layer, a second surface being opposite to the first surface, and a side surface connecting the first surface and the second surface to each other, and
a width of the first surface of the tip is less than a width of the second surface of the tip.

5. The display device as claimed in claim 4, wherein the width of the second surface of the tip has a value greater than the thickness of the first bank layer.

6. The display device as claimed in claim 5, wherein a first inclination angle between the first surface and the side surface is an obtuse angle, and
a second inclination angle between the second surface and the side surface is an acute angle.

7. The display device as claimed in claim 6, wherein the second inclination angle is less than or equal to 50 degrees.

8. The display device as claimed in claim 1, wherein the pixel defining layer defines an opening,
the tip of the second bank layer is around the opening, and
a side surface of the pixel defining layer protrudes toward the emission area further than the side surface of the first bank layer.

9. The display device as claimed in claim 1, further comprising:
a cathode electrode on the light emitting element layer; and
an organic pattern provided on the second bank layer, containing the same material as the light emitting element layer, and being spaced apart from the light emitting element layer,
wherein the cathode electrode completely covers the organic pattern.

10. The display device as claimed in claim 1, wherein the light emitting element layer comprises at least one of a hole injection layer, a hole transport layer, and an electron transport layer.

11. The display device as claimed in claim 1, wherein the anode electrode comprises a first anode electrode and a second anode electrode that are spaced apart from each other while the pixel defining layer is between the first anode electrode and the second anode electrode, and
the first anode electrode and the second anode electrode are at different heights.

12. The display device as claimed in claim 11, further comprising:
a first metal pattern between the substrate and the first anode electrode; and
a second metal pattern between the substrate and the second anode electrode,
wherein the first metal pattern comprises a first insulating layer, and the second metal pattern comprises a second insulating layer, and
a thickness of the first insulating layer and a thickness of the second insulating layer are different from each other.

13. A method for fabricating a display device, comprising:
providing a temporary protective layer having a normal tapered shape on an anode electrode;
providing a pixel defining layer, a first bank layer, and a second bank layer that cover the temporary protective layer;
providing a tip of the second bank layer and an opening of the pixel defining layer by performing an etching process; and
providing a light emitting layer and a cathode electrode on the anode electrode,
wherein in the providing of the pixel defining layer, the first bank layer, and the second bank layer that cover the temporary protective layer, a thickness of the second bank layer is greater than or equal to a thickness of the first bank layer.

14. The method as claimed in claim 13, wherein in the providing of the pixel defining layer, the first bank layer, and the second bank layer that cover the temporary protective layer, the pixel defining layer, the first bank layer, and the second bank layer cover the temporary protective layer along its shape to have a stepped portion in a normal tapered shape.

15. The method as claimed in claim 14, wherein in the providing of the tip of the second bank layer and the opening of the pixel defining layer by performing the etching process, the tip of the second bank layer has a reverse tapered shape.

16. An electronic device comprising:
at least one display device comprising a substrate comprising an emission area and a non-emission area; and
at least one selected from among a processor, a memory, and a power module that are connected to the at least one display device,
wherein the at least one display device further comprises:
an anode electrode on the emission area of the substrate;
a pixel defining layer provided on the non-emission area of the substrate and covering an edge of the anode electrode;
a bank structure comprising a first bank layer on the pixel defining layer and a second bank layer having a tip protruding toward the emission area further than a side surface of the first bank layer; and
a light emitting element layer provided on the anode electrode and comprising a first light emitting element layer and a second light emitting element layer that are spaced apart from each other while the bank structure is between the first light emitting element layer and the second light emitting element layer,
wherein the tip of the second bank layer has a reverse tapered shape, and
a thickness of the tip of the second bank layer is greater than or equal to a thickness of the first bank layer.

17. The electronic device as claimed in claim 16, wherein the first bank layer and the second bank layer contain an inorganic insulating material.

18. The electronic device as claimed in claim 17, wherein the first bank layer and the second bank layer contain different materials.

19. The electronic device as claimed in claim 16, wherein the tip of the second bank layer comprises a first surface being opposite to the first bank layer, a second surface being opposite to the first surface, and a side surface connecting the first surface and the second surface to each other, and
a width of the second surface of the tip has a value greater than the thickness of the first bank layer.

20. The electronic device as claimed in claim 19, wherein a first inclination angle between the first surface and the side surface is an obtuse angle,
a second inclination angle between the second surface and the side surface is an acute angle, and
the second inclination angle is less than or equal to 50 degrees.
